(19) United States
(12) Patent Application Publication
(10) Pub. No.: US 2022/0391708 A1
(43) Pub. Date: Dec. 8, 2022

(54) Geometric Learning-Based Method for Discovery of Optical Phenomena in Nanophotonic Structures

(71) Applicant: Georgia Tech Research Corporation, Atlanta, GA (US)

(72) Inventors: Yashar Kiarashinejad, Atlanta, GA (US); Mohammadreza Zandehshahvar, Atlanta, GA (US); Sajjad Abdollahramezani, Atlanta, GA (US); Omid Hemmatyar, Atlanta, GA (US); Ali Adibi, Atlanta, GA (US)

(21) Appl. No.: 17/474,523

(22) Filed: Sep. 14, 2021

Related U.S. Application Data
(63) Continuation of application No. 17/233,140, filed on Apr. 16, 2021, now abandoned.
Application No. 17/233,140 is a continuation of application No. 17/010,262, filed on Sep. 2, 2020, now abandoned.
(60) Provisional application No. 62/895,466, filed on Sep. 3, 2019.

(51) Int. Cl. G06N 3/08; G06N 3/04; G06N 20/10

(52) U.S. Cl. CPC G06N 3/088; G06N 3/0454; G06N 3/0427; G06N 20/10

(57) ABSTRACT

An exemplary embodiment of the present disclosure provides a system and method for identifying a first plurality of data points comprising a design space and a response space, the method including computing a first convex hull of all data points in the plurality of data points, merging the first convex hull with previous convex hulls to form an optimized convex hull, the previous convex hulls comprising a second plurality of data points comprising previous design spaces and previous response spaces, and determining, by the optimized convex hull, a feasible optical response performance within an electromagnetic nanostructure.

### CROSS-REFERENCE TO RELATED APPLICATIONS

This application is a continuation application of U.S. patent application Ser. No. 17/233,140, filed on 16 Apr. 2021, which is a continuation application of U.S. patent application Ser. No. 17/010,262, filed on 2 Sep. 2020, which claims the benefit of U.S. Provisional Application Ser. No. 62/895,466, filed on 3 Sep. 2019, the contents of which are incorporated herein by reference in its entirety as if fully set forth below.

### FEDERALLY SPONSORED RESEARCH STATEMENT

This invention was made with government support under grant/award number N00014-18-1-2055 awarded by the Office of Naval Research. The government has certain rights in the invention.

### FIELD OF THE DISCLOSURE

The various embodiments of the present disclosure relate generally to systems and methods for enhanced engineering design and optimization capable of providing feasible optical response solutions for design parameters and output characteristics, and more particularly to systems and methods for enhanced engineering design and optimization of complex electromagnetic structures.

### BACKGROUND

While electronic design is well established, nanophotonic integrated circuits are a fast-emerging domain and present design technologies are inadequate. Traditional design and optimization approaches for such nanophotonic structures rely on using analytical or semi-analytical modeling or even brute-force analysis. Such approaches are limited to structures having relatively simple designs due to the complex computational requirements to completely study and model such structures.

Further, as researchers are able to form increasingly more complex nanostructures with multiple design parameters, these traditional design methods and optimization approaches become less and less feasible. For example, as the number of design parameters increases so does the computational requirements for generating and analyzing such designs. Additionally, as such nanostructures become more and more complex, it becomes ever more important to understand and quickly identify whether a variety of design options and parameters may achieve a feasible optical response.

Some emerging solutions have suggested combatting these problems by utilizing neural networks, however such solutions have been limited to the simple nanostructures due to the reduced computational complexity afforded due to the one-to-one relationship between design parameters and output response. However, such approaches fail to account for the fact that most of the most promising nanostructures do not exhibit such a one-to-one relationship, thus such solutions ultimately provide little to no improvement over the brute force techniques. Additionally, these methods tend to focus on optimization of a nanostructure rather than learning the physical phenomena or possible responses that can be achieved from a structure or alternatively, the potential of a given structure providing a range of possible responses. Learning this information can assist in designing considerably simpler and fabricationally favorable structures.

Accordingly, there is a need for systems and methods for assessing feasibility of a desired response of a given design and feasibility for design parameters exhibiting a many-to-one relationship between design parameters and output characteristics. Specifically, there is a need for systems and methods for assessing feasibility of desired optical responses of complex electromagnetic nanostructures. Examples of the present disclosure are directed to these and other considerations.

### BRIEF SUMMARY

Examples of the present disclosure comprise systems and methods for detecting feasible optical response performances from a structure having design parameters and limitation parameters, and more particularly to systems and methods for identifying feasibility of desired responses achievable in a photonic nanostructure.

An exemplary embodiment of the present disclosure provides a system for detecting a feasible optical response performance from a structure. The system can comprise one or more processors and at least one memory in communication with the one or more processors and configured to store instructions. The instructions, when executed by the one or more processors, can be configured to cause the system to collect input design data, identify limitation data, generate simulation data, train a first multi-layer neural network, train a second neural network, generate an optimization convex hull, and invert a design space and a response space to generate the feasible optical response performance from the structure.

In some embodiments, identifying limitation data can be based on the input design data. Generating simulation data can be based on the limitation data and can comprise a design space and a response space. Training the first multi-layer neural network can utilize the response space. The first multi-layer neural network can be trained to generate a reduced response space having reduced dimensionality compared to the response space. The first multi-layer neural network can comprise an encoding layer and a decoding layer. Train the second neural network can utilize the design space and the response space. The second neural network can be trained to generate a reduced design space having reduced dimensionality compared to the design space. The optimization convex hull can be generated by cascading the second neural network with the decoding layer of the first multi-layer neural network. Inverting the design space and the response space can use the optimization convex hull to generate the feasible optical response performance from the structure.

In some embodiments, wherein the instructions can be further configured to cause the system to determine a designation of overlapping or non-overlapping of a desired design space of a desired structure. The designation of overlapping or non-overlapping can be determined by using the optimization convex hull.

In some embodiments, the instructions can be further configured to cause the system to validate, by using validation data, the optimization convex hull.

In some embodiments, the input design data can comprise a plurality of randomly generated patterns of a simulated structure.

In some embodiments, limitation data can comprise structural limitation data relating to physical properties of a photonic nanostructure.

In some embodiments, the photonic nanostructure can comprise a metasurface.

In some embodiments, the first multi-layer neural network can be an autoencoder.

In some embodiments, the autoencoder can utilize mean squared error as a cost function.

In some embodiments, the simulation data can comprise a multi-dimensional response space.

In some embodiments, the simulation data can comprise at least a six-dimensional response space.

In some embodiments, the response space and the reduced response space have a one-to-one dimensional relationship.

In some embodiments, the reduced design space and the reduced response space have a one-to-one dimensional relationship.

An exemplary embodiment of the present disclosure provides a method comprising identifying a first plurality of data points, computing a first convex hull, merging the first convex hull with previous convex hulls, and determining a feasible optical response performance within an electromagnetic nanostructure. The first plurality of data points can comprise a design space and a response space. The first convex hull can include all data points in the first plurality of data points. Merging the first convex hull with previous convex hulls can form an optimized convex hull. The previous convex hulls can comprise a second plurality of data points comprising previous design spaces and previous response spaces. The feasible optical response performance within an electromagnetic nanostructure can be determined by using the optimized convex hull.

In some embodiments, the method can further comprise inverting, using the optimized convex hull, the design space and the response space to generate the feasible optical response performance from the electromagnetic nanostructure.

In some embodiments, inverting, using the optimized convex hull, the design space and the response space can further comprise applying a one-class support vector machine algorithm.

In some embodiments, inverting, using the optimized convex hull, the design space and the response space can further comprise designating a desired design space of a desired electromagnetic nanostructure as overlapping or non-overlapping the optimized convex hull.

In some embodiments, the method can further comprise merging, using the optimized convex hull and third plurality of data points from a desired electromagnetic nanostructure structure, a re-optimized convex hull when the desired electromagnetic nanostructure comprises a desired design space designated as non-overlapping.

An exemplary embodiment of the present disclosure provides a system for detecting a feasible optical response performance from an electromagnetic nanostructure. The system can comprise one or more processors and at least one memory in communication with the one or more processors and configured to store instructions. The instructions, when executed by the one or more processors, can be configured to cause the system to collect input electromagnetic nanostructure design data; identify, based on the input electromagnetic nanostructure design data, structural limitation data comprising material properties, potential nanostructure geometry, periodic/non-periodic, unit-cell structure, and fabrication limitations; generate, based on the structural limitation data, electromagnetic simulation data comprising a design space, the design space comprising a set of design patterns and a corresponding response space comprising a corresponding set of response patterns; train, utilizing the corresponding response space, a first multi-layer neural network to generate a reduced response space having reduced dimensionality compared to the corresponding response space, the first multi-layer neural network comprising an encoding layer and a decoding layer; train, utilizing the design space and the corresponding response space, a second neural network to generate a reduced design space having reduced dimensionality compared to the design space; generate, by cascading the second neural network with the decoding layer of the first multi-layer neural network, an optimization convex hull; and invert, using the optimization convex hull, the design space and the corresponding response space to generate the feasible optical response performance from the electromagnetic nanostructure.

In some embodiments, the instructions can be further configured to cause the system to determine, by using the optimization convex hull, a designation of overlapping or non-overlapping of a desired design space of a desired structure.

In some embodiments, the electromagnetic simulation data can comprise a multi-dimensional response space ranging from about 2-dimensional to about 6-dimensional.

Further features of the disclosed design, and the advantages offered thereby, are explained in greater detail hereinafter with reference to specific examples illustrated in the accompanying drawings, wherein like elements are indicated by like reference designators.

These and other aspects of the present disclosure are described in the Detailed Description below and the accompanying drawings. Other aspects and features of embodiments will become apparent to those of ordinary skill in the art upon reviewing the following description of specific, exemplary embodiments in concert with the drawings.

While features of the present disclosure may be discussed relative to certain embodiments and figures, all embodiments of the present disclosure can include one or more of the features discussed herein. Further, while one or more embodiments may be discussed as having certain advantageous features, one or more of such features may also be used with the various embodiments discussed herein. In similar fashion, while exemplary embodiments may be discussed below as device, system, or method embodiments, it is to be understood that such exemplary embodiments can be implemented in various devices, systems, and methods of the present disclosure.

### BRIEF DESCRIPTION OF THE DRAWINGS

The following detailed description of specific embodiments of the disclosure will be better understood when read in conjunction with the appended drawings. For the purpose of illustrating the disclosure, specific embodiments are shown in the drawings. It should be understood, however, that the disclosure is not limited to the precise arrangements and instrumentalities of the embodiments shown in the drawings.

FIGS. 1A and 1B provide example systems and methods that may be used to implement one or more examples of the present disclosure.

FIG. 1C provides a diagram of an example system that may be used to implement one or more examples of the present disclosure.

FIGS. 2A and 2B provide example electromagnetic nanostructures having nanocubes, in accordance with an exemplary embodiment of the present disclosure.

FIG. 2C provides an example electromagnetic nanostructure having nanopillars, in accordance with an exemplary embodiment of the present disclosure.

FIG. 3A provides a plot of dimensionality versus mean squared error for reflection responses of an example electromagnetic nanostructure, in accordance with an exemplary embodiment of the present disclosure.

FIG. 3B provides a dual-plot depicting the performance of the system and method of FIG. 1A, in accordance with an exemplary embodiment of the present disclosure.

FIG. 4A provides a 2D plot of an example convex hull depicting feasible response space of the example nanostructure in FIG. 2B, in accordance with an exemplary embodiment of the present disclosure.

FIG. 4B provides a 3D plot of an example convex hull depicting feasible response space of the example nanostructure in FIG. 2B, in accordance with an exemplary embodiment of the present disclosure.

FIG. 4C provides a plot of non-convex geometry for feasible responses using the example system and method of FIG. 1B, in accordance with an exemplary embodiment of the present disclosure.

FIG. 5A provides a 2D plot of an example convex hull depicting feasible response space of simulation data of the example nanostructure in FIG. 2C, in accordance with an exemplary embodiment of the present disclosure.

FIG. 5B provides a 3D plot of an example convex hull depicting feasible response space of simulation data of the example nanostructure in FIG. 2C, in accordance with an exemplary embodiment of the present disclosure.

FIG. 5C provides a plot of non-convex geometry for feasible responses using the example system and method of FIG. 1B, in accordance with an exemplary embodiment of the present disclosure.

FIG. 6A provides SEM images of an example nanostructure, in accordance with an exemplary embodiment of the present disclosure.

FIG. 6B provides simulated and measured reflectance spectra of example nanostructures having square lattices with varying dimensions (p=390 nm, 410 nm, and 450 nm) and nanopillars with radii of r=0.75 p, in accordance with an exemplary embodiment of the present disclosure.

FIG. 7A provides a 2D plot of an example convex hull depicting feasible response space of an example nanostructure of FIG. 2C, in accordance with an exemplary embodiment of the present disclosure.

FIG. 7B provides a 3D plot of an example convex hull depicting feasible response space of an example nanostructure of FIG. 2C, in accordance with an exemplary embodiment of the present disclosure.

FIG. 7C provides a plot of non-convex geometry for feasible responses using the example system and method of FIG. 1B, in accordance with an exemplary embodiment of the present disclosure.

FIG. 8 provides an example non-convex set of points (left) and the resulting convex hull (right), in accordance with an exemplary embodiment of the present disclosure.

FIG. 9 provides an example convex hull (left) adding the farthest point in the outside set to the convex hull at each iteration (right), in accordance with an exemplary embodiment of the present disclosure.

FIGS. 10A and 10B provide an example Inhull function for finding points inside and outside of the convex hull, in accordance with an exemplary embodiment of the present disclosure.

FIG. 11 provides an example one-class SVM in an example original space and an example kemelized space, in accordance with an exemplary embodiment of the present disclosure.

FIGS. 12A-12C provide example schematics of nanostructures for achieving Fano-lineshape responses, in accordance with an exemplary embodiment of the present disclosure.

FIG. 12D provides a plot of achievable Fano-lineshapes from example nanostructures of FIGS. 12A-12C, in accordance with an exemplary embodiment of the present disclosure.

FIG. 13 provides a plot of dimensionality versus mean squared error for an example electromagnetic nanostructure, in accordance with an exemplary embodiment of the present disclosure.

FIG. 14A provides a plot of non-convex geometry for feasible responses using the example system and method of FIG. 1B, in accordance with an exemplary embodiment of the present disclosure.

FIG. 14B provides a plots of responses achieved from an example nanostructure with 20 random design parameters, in accordance with an exemplary embodiment of the present disclosure.

FIG. 15A provides an example system and method for forming a manifold-learning based approach, in accordance with an exemplary embodiment of the present disclosure.

FIG. 15B provides an example system and method for forming an inverse based approach, in accordance with an exemplary embodiment of the present disclosure.

FIG. 16A provides example nanostructures having varied geometric complexities, in accordance with an exemplary embodiment of the present disclosure.

FIGS. 16B and 16C provide example reflection responses (FIG. 16B) and latent-space representations of the reflection responses (FIG. 16C) of the example nanostructures of FIG. 16A, in accordance with an exemplary embodiment of the present disclosure.

FIGS. 17A and 17B provide resonance wavelength distribution (FIG. 17A) and high/low-Q distribution (FIG. 17B) of responses of the example nanostructures of FIG. 16A in the latent space, in accordance with an exemplary embodiment of the present disclosure.

FIG. 17C provides a reflection response of an example effect of rotation of a nanostructure, in accordance with an exemplary embodiment of the present disclosure.

FIG. 18A provides an example latent-space representation of the reflection responses of the example nanostructures of FIG. 16A with two locations marked with a square correlating to FIG. 18B and a triangle correlating to FIG. 18C, in accordance with an exemplary embodiment of the present disclosure.

FIGS. 18B and 18C provide desired and corresponding optimized reflection responses correlating to locations identified in FIG. 18A, in accordance with an exemplary embodiment of the present disclosure. The ideal reflection responses are found by the example system and method of FIG. 15B.

FIGS. 19A-19D provide nearfield simulation of the example nanostructures of FIG. 16A, in accordance with an exemplary embodiment of the present disclosure.

FIGS. 20A and 20B provide example deep-learning techniques for designing nanostructures, in accordance with an exemplary embodiment of the present disclosure.

FIG. 21 provides an example deep-learning pseudoencoder technique for designing nanostructures, in accordance with an exemplary embodiment of the present disclosure.

FIG. 22 provides an example schematic of a multi-layer thin-film nanostructure, in accordance with an exemplary embodiment of the present disclosure.

FIGS. 23A and 23B provide example design parameters (FIG. 23A) and corresponding transmission responses (FIG. 23B) for each example design parameter for the example nanostructure of FIG. 22, in accordance with an exemplary embodiment of the present disclosure.

FIGS. 24A and 24B provide a plot of dimensionality versus mean squared error (FIG. 24A) and the corresponding transmission response with different dimensionalities for the example nanostructure of FIG. 22, in accordance with an exemplary embodiment of the present disclosure.

FIGS. 25A and 25B provide desired responses and inverse-design responses for the example nanostructure of FIG. 22, in accordance with an exemplary embodiment of the present disclosure.

### DETAILED DESCRIPTION

To facilitate an understanding of the principles and features of the present disclosure, various illustrative embodiments are explained below. The components, steps, and materials described hereinafter as making up various elements of the embodiments disclosed herein are intended to be illustrative and not restrictive. Many suitable components, steps, and materials that would perform the same or similar functions as the components, steps, and materials described herein are intended to be embraced within the scope of the disclosure. Such other components, steps, and materials not described herein can include, but are not limited to, similar components or steps that are developed after development of the embodiments disclosed herein.

Here, the inventors present a new approach based on geometric deep learning to measure the viability of certain optical responses from a class of nanostructures. Design of nanostructures always comes with having some constraints (e.g., size, shape, and material properties). Due to these constraints, some responses are not practical for a certain class of nanostructure by any means (any set of design parameters). In case a given response is impossible to achieve using a class of nanostructure, instead of searching blindly over all possible design parameters, which is expensive in time and resource, this approach leads to a change in the structure. The algorithm can first reduce the dimensionality of the response space using the ground truth data generated by commercial full-wave simulators. Then, the platform can be trained to find the optimum convex hull to bound the feasible responses in the latent space. This can be done through an iterative process until convergence. Next, a one-class SVM algorithm can be applied to find the non-convex geometry of achievable responses. The method was applied to two different classes of metasurfaces (MSs) in the visible range: (i) digital MSs consisting of 7×7 and 14×14 binary plasmonic nano-cubes associated with sophisticated numerical reflectance responses, and (ii) engineered MSs comprising of a square-lattice array of dielectric nano-ellipsoids associated with numerical and experimental Fano-type sharp resonances. The systems and methods described herein can accelerate current design approaches and grant priceless information about what a specific class of photonics nanostructure is capable to offer.

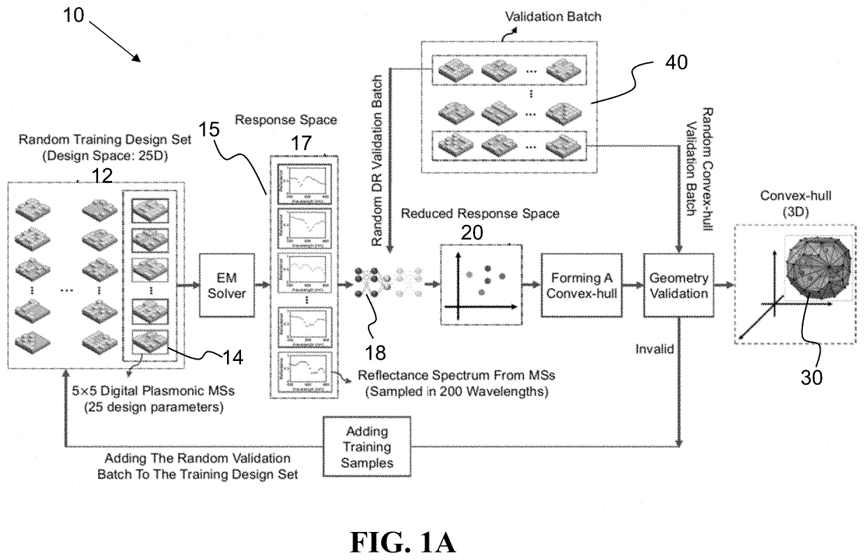

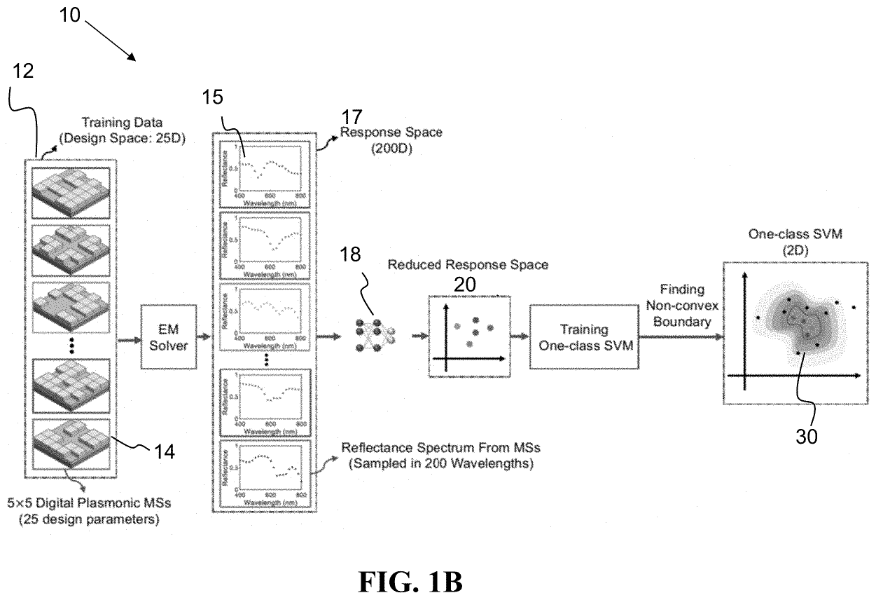

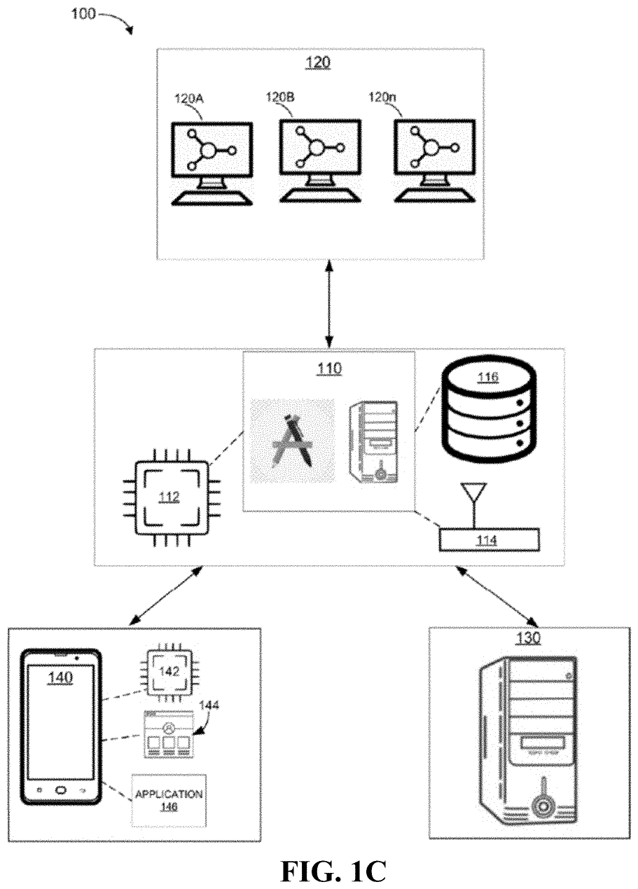

As shown in FIG. 1A, an exemplary embodiment of the present invention provides a system 10 for detecting a feasible optical response performance from a structure. In some embodiments, system 10 can be caused to collect input design data 12, identify limitation data 14, generate simulation data 15, train a first multi-layer neural network 18, train a second neural network 22, generate an optimization convex hull 30, and invert the optimization convex hull to generate the feasible optical response performance 40 from the structure.

Input design data 12 can include data characterizing one or more nanostructures having randomly generated patterns using a full-wave EM simulation software (e.g., EM simulation software can include suitable computational tools such as Numerical Electromagnetics Code (NEC), Momentum, High-Frequency Structure Simulator (HFSS), XFdtd, AWR Axiem, AWR Analyst, JCMsuite, COMSOL Multiphysics, FEKO, and Elmer FEM). Additionally or alternatively thereto, input design data 12 can include data characterizing an EM wave solver using an analytic or a semi-analytic model.

As shown in FIG. 1A, based on input design data 12, system 10 can be caused to identify limitation data 14. In general, limitation data 14 can include structural limitation data characterizing physical properties of a photonic nanostructure. Limitation data 14 can include data characterizing the structure of a physical product to be designed. For example, limitation data 14 may include data characterizing material properties, potential nanostructure geometry, periodic/non-periodic, unit-cell structure, and fabrication limitations. Limitation data 14 can include data received from a user (e.g., user device 140, see FIG. 1C) and/or or limitation data received from the server 130. In some embodiments, limitation data 14 can include structural limitation data characterizing physical properties of a photonic nanostructure, such as, for example, a metasurface.

Based on limitation data 14, system 10 can be caused to generate simulation data 15. Simulation data 15 can include a plurality of design spaces 16 (e.g., all possible designs) and a plurality of response spaces 17 (e.g., all possible responses). The relationship between design space 16 and response space 17 for a structure can be a one-to-one relationship or a many-to-one relationship. A many-to-one relationship between a design space 16 and a response space 17 may indicate that multiple sets of design parameters may result in a given response. As will be appreciated, such a many-to-one relationship can lead to a non-uniqueness problem, meaning that there may be more than one solution for a given desired response. As will be further appreciated, many-to-one problems can also involve a great deal of computational complexity in order to arrive at one of the many nonunique solutions. It is such problems that system 10 seeks to solve.

As depicted in FIG. 1A, system 10 can further be caused to train first multi-layer neural network 18 using the response space 17. First multi-layer neural network 18 can be trained to generate a reduced response space 20. Reduced response space 20 may have a reduced dimensionality compared to response space 17. First multi-layer neural network 18 can include an encoding layer, a decoding layer, and optionally one or more hidden layers. In some embodiments, the first multi-layer neural network can be an autoencoder that dimensionally reduces response space 17 to generate reduced response space 20. The one or more hidden layers can range from 3 to 9. The autoencoder can utilize mean squared error as the cost function. The autoencoder can minimize error using the backpropagation method. The activation function for the neural network can comprise one of rectified linear unit (Relu) and tangent hyperbolic. The training optimizer for the neural network can comprise one of adaptive moment estimation, stochastic gradient descent, mini-batch gradient descent, and other suitable optimizers. The learning rate for the neural network can be between 10⁻⁶ and 10⁻⁵. First multi-layer neural network 18 can include any suitable machine learning or deep learning-based technique including, without limitation, a feedforward neural network, an autoencoder, or a pseudoencoder. A feedforward neural network can be trained to map design space into the response space. An autoencoder can be trained to reduce the dimensionality of the response space. A psuedoencoder can be composed of networks from the design space to the reduced design space, from the reduced design space to the reduced response space, or from the decoder part of the autoencoder to the response space to reduce the dimensionality of the design space.

In some embodiments, system 10 can further be caused to train second neural network 22 using the design space 16 and response space 17. Second neural network 22 can be trained to generate a reduced design space 24 having reduced dimensionality compared to design space 16. The second neural network 22 can be similar to first multi-layer neural network 18 and can include an encoding layer, a decoding layer, and optionally one or more hidden layers. In some embodiments, the second neural network 22 can be an autoencoder that dimensionally reduces design space 16 to generate reduced design space 24.

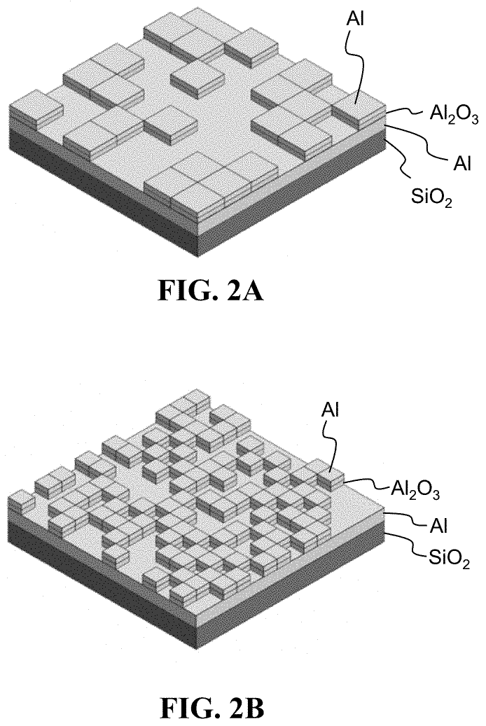

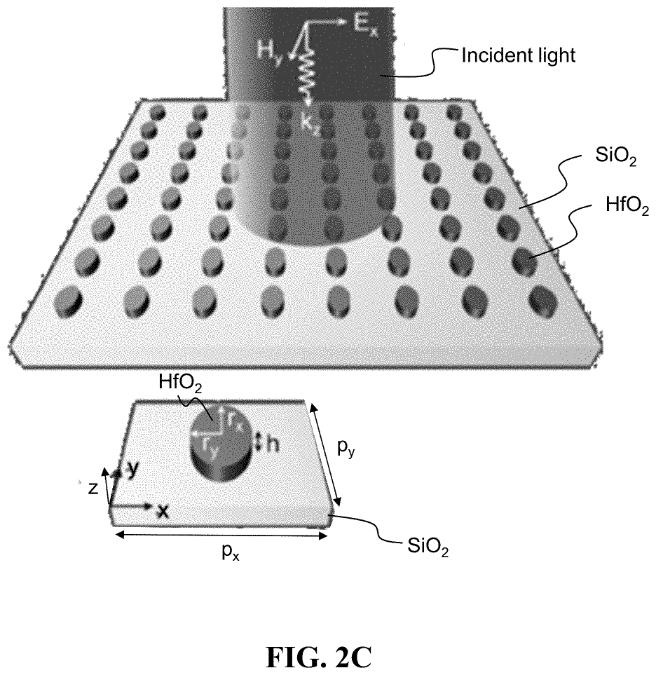

As depicted in FIG. 1A, system 10 can be caused to generate the optimization convex hull 30 by cascading the second neural network with the decoding layer of the first multi-layer neural network. Optimization convex hull 30 can bind the feasible response spaces in a latent space (e.g., in 3D as shown in FIG. 1A or 2D as provided in FIG. 1B). As described in more detail below in Example 1, optimization convex hull 30 can include a set of points that can be defined as the smallest convex set that contains all those points.

After forming optimization convex-hull 30, system 10 can further be caused to use optimization convex hull 30 to invert the design space 16 and response space 17 and generate the feasible optical response performances that a structure can achieve.

In some embodiments, system 10 can additionally be caused to use optimization convex hull 30 to determine a designation of either overlapping or non-overlapping of a desired design space of a desired structure. When system 10 designates a desired design space as overlapping, system 10 can provide design parameters possible to generate the desired optical response. Alternatively, when system 10 designates a desired design space as non-overlapping, system 10 can inform that a desired optical response is not possible with the desired design space and thereby accelerate alternative design approaches.

FIG. 1B shows example system 10 for detecting a feasible optical response performance from a structure. In some embodiments, system 10 can be caused to collect input design data 12, identify limitation data 14, generate simulation data 15, train a first multi-layer neural network 18 to generate a reduced response space 20, and further apply a one-class support vector machine (SVM) algorithm to the reduced response space 20 to find the non-convex geometry. One-class SVM can also provide information about the level of feasibility (or non-feasibility) of a response and the possibility of trading an acceptable error (or a small change in the desired response) to get the closest feasible response from a non-feasible one.

FIG. 1C shows an example system 100 that may implement certain methods for engineering design and optimization as disclosed herein. As shown in FIG. 1C, in some implementations the system 100 can include one or more simulation devices 120A-120n, a server 130, a user device 140, and a design and optimization server 110, which may include one or more processors 112, a transceiver 114, and a database 116, among other things. The user device 140 can include one or more processors 142, a graphical user interface (GUI) 144, and an application 146.

The simulation devices 120A-120n can represent computer simulation devices and/or one or more neural networks that have been pre-trained based on simulation data. The server 130 may belong to a third-party aggregator, for example, that stores data, such as neural network training data, simulation data, or other data necessary to implement the methods described herein.

The user device 140 can be, for example, a personal computer, a smartphone, a laptop computer, a tablet, a wearable device (e.g., smart watch, smart jewelry, head-mounted displays, etc.), or another computing device. An example computer architecture that can be used to implement the user device 140 is described below with reference to FIG. 1A. The design and optimization server 110 can include one or more physical or logical devices (e.g., servers) or drives and may be implemented as a single server, a bank of servers (e.g., in a “cloud”), run on a local machine, or run on a remote server. An example computer architecture that can be used to implement the design and optimization server 110 is described below with reference to FIG. 1B.

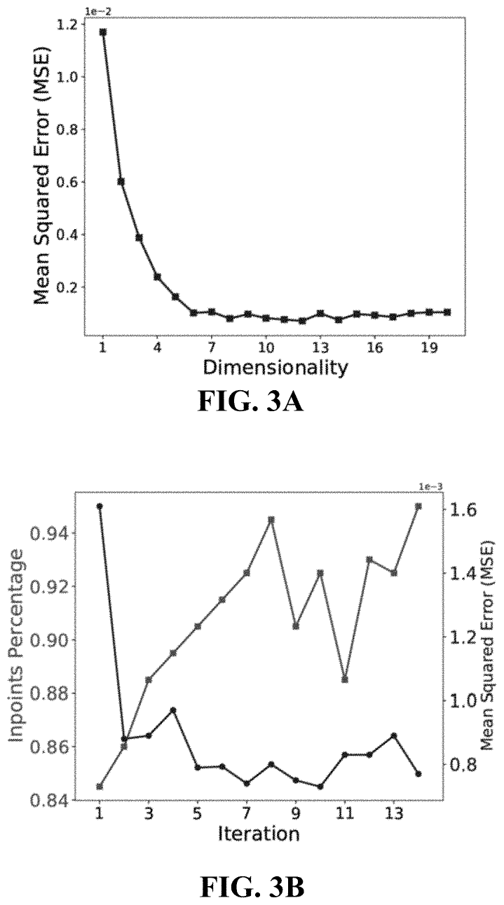

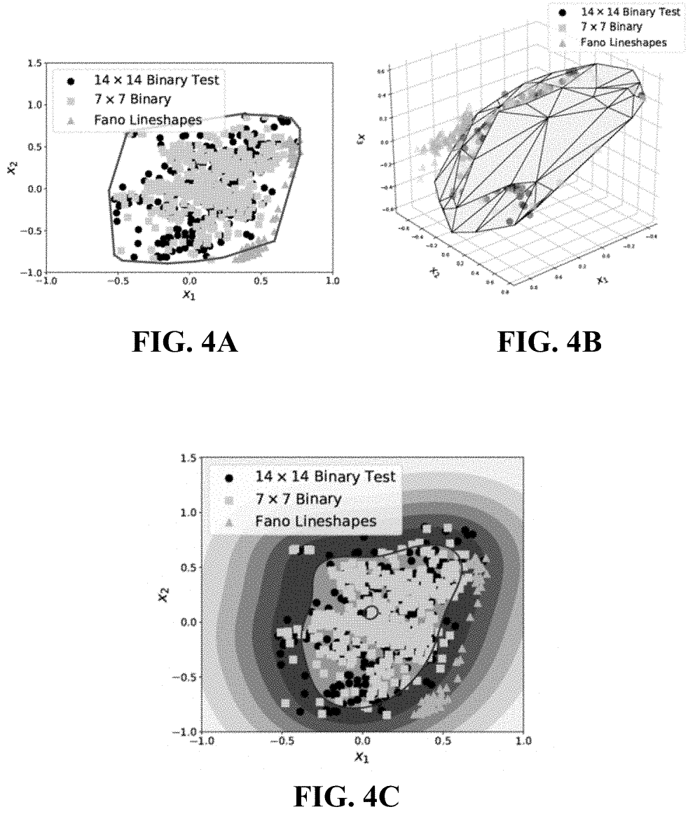

Examples of electromagnetic nanostructures are illustrated in FIGS. 2A through 2C. FIGS. 3A and 3B provide data relating to the performance of system 10 relative to dimensionality. FIGS. 4A-4C, 5A-5C, and 7A-7C illustrate example 2D convex-hull, 3D convex-hull, and non-convex geometry for feasible responses of example nanostructures provided in FIGS. 2A, 2B, and 2C, respectively, using system 10.

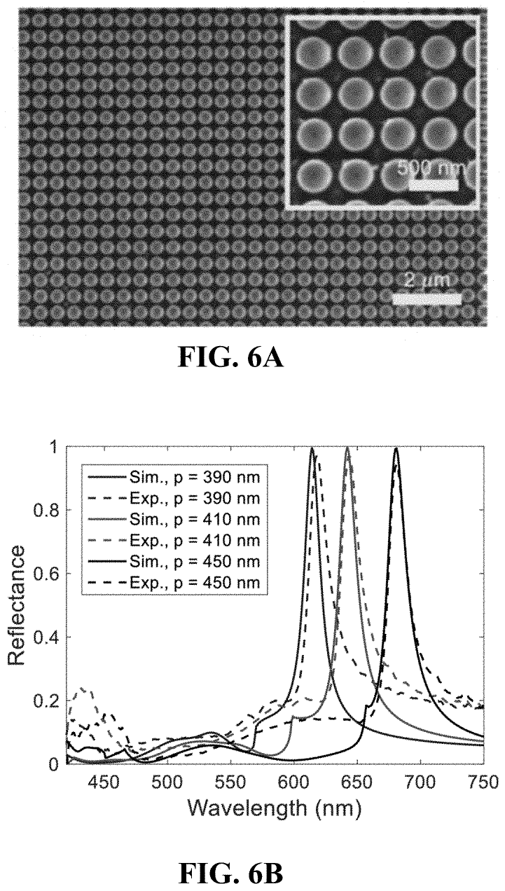

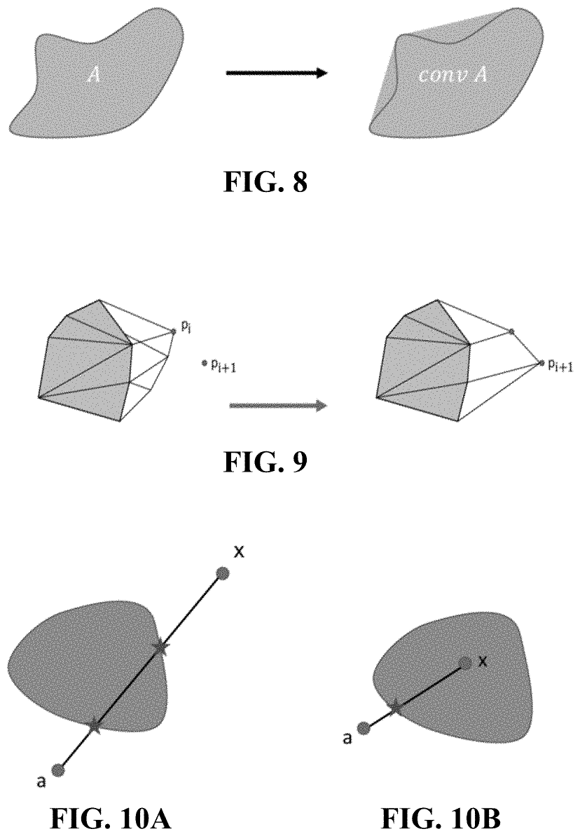

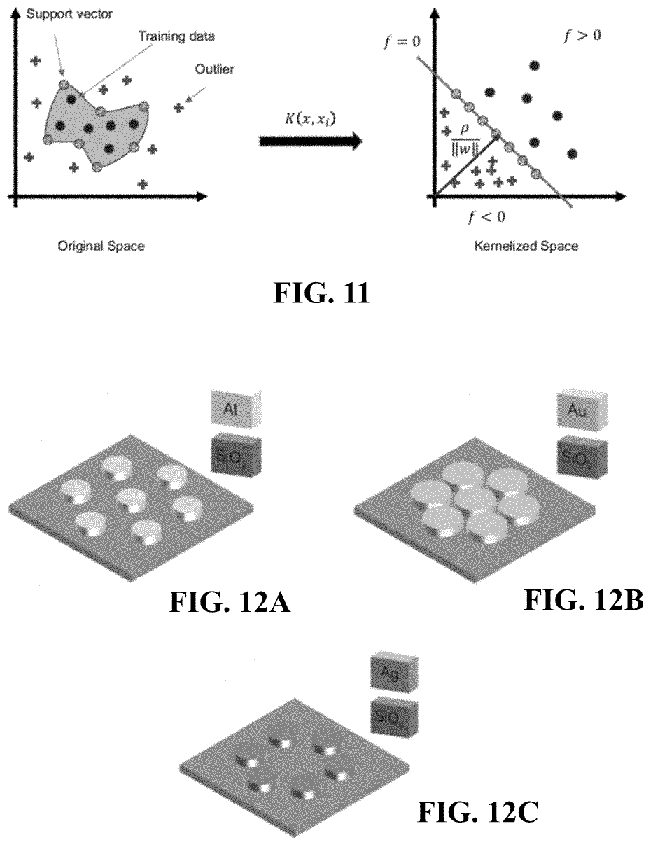

An example electromagnetic nanostructure is provided in FIG. 6A. Simulated and measured data relating to the reflectance is shown in FIG. 6B. Example convex hulls are illustrated in FIGS. 8-10B. An example one-class SVM is shown in FIG. 11.

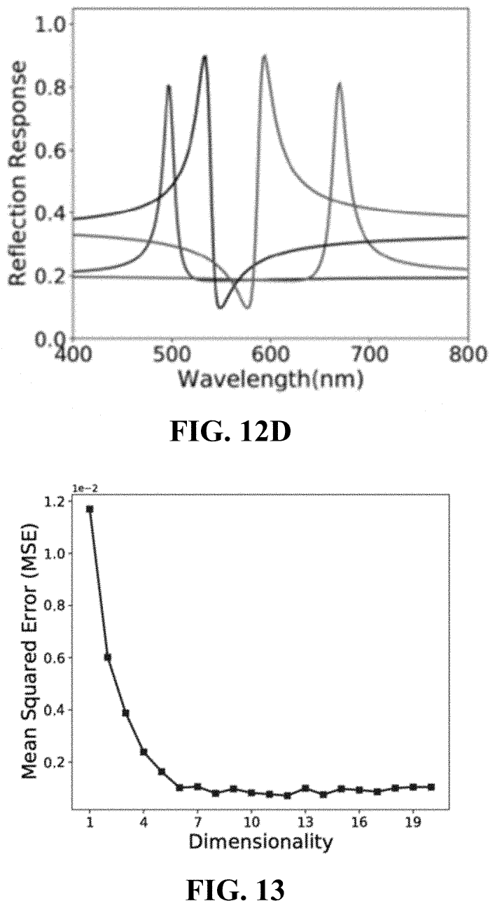

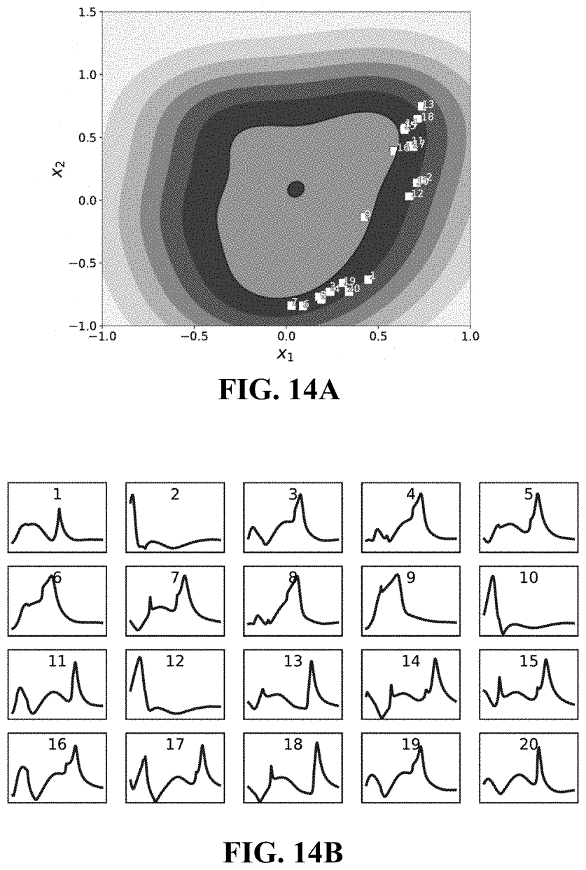

Examples of electromagnetic nanostructures are illustrated in FIGS. 12A through 12C with achievable Fano-lineshapes provided in FIG. 12D. FIG. 13 provides data relating to the performance of system 10 relative to dimensionality. FIGS. 14 illustrates a non-convex geometry for feasible responses of nanostructures having random design parameters and FIG. 14B provides achievable Fano-lineshapes within and outside the non-convex geometry.

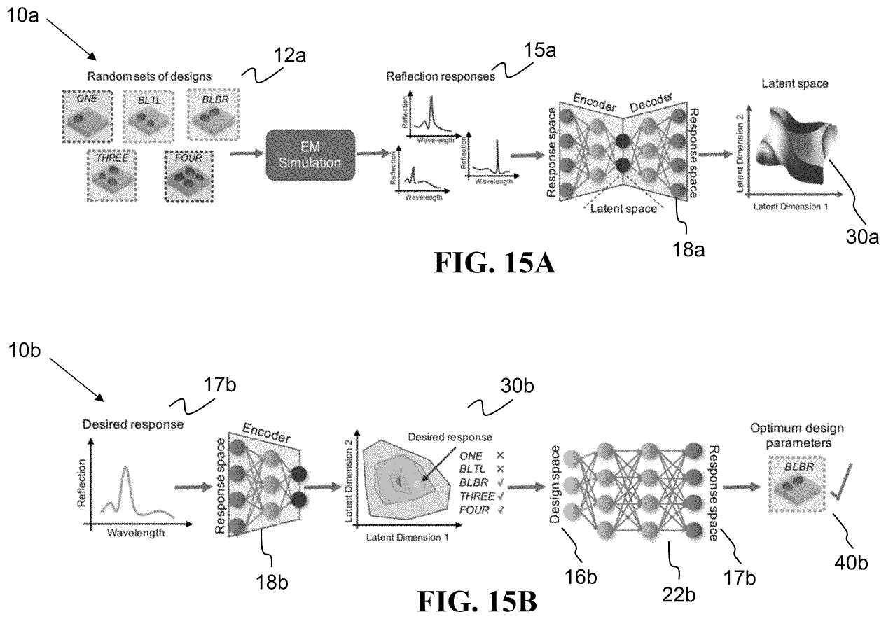

As shown in FIG. 15A, an example embodiment provides a variation of system 10 (denoted by reference numeral 10a in FIG. 15A) for determining a feasible optical response performance from a structure. In some embodiments, system 10a can be adjusted to form a latent space of the responses (i.e., identify sub-manifolds in the hidden space). System 10a can be caused to collect input design data 12a comprising random sets of designs, generate simulation data 15a, train a first multi-layer neural network 18a to generate a reduced response space 20a, and model, using a Gaussian mixture model, one or more latent spaces 30a corresponding to the reduced response space 20a to find an optimum design parameter.

FIG. 15B provides an example embodiment of a variation of system 10 (denoted by reference numeral 10b in FIG. 15bB) for determining an optimum design parameter 40b from a desired response 17b. As shown, system 10b can include an inverse design to determine the optimum design parameter. System 10b can be caused to train a multi-layer neural network 18b to generate a latent space 30b based on input design data 12a comprising random sets of designs, and relate, using a second multi-layer neural network 22b, the design space 16b into a latent response space 30b to generate the optimum design parameter 40b.

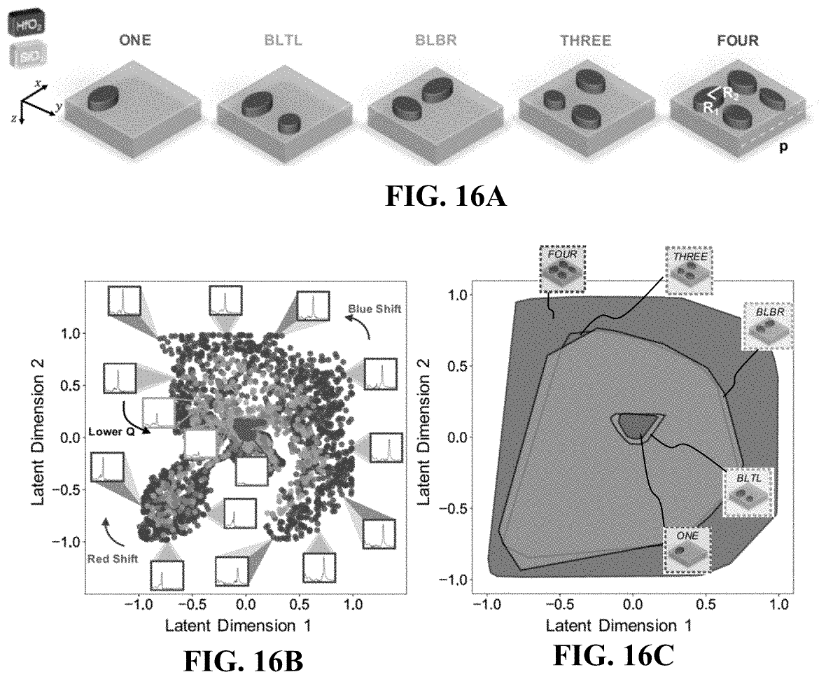

FIG. 16A provides example nanostructures having varied geometric complexities from one nanopillar to four nanopillars. FIGS. 16B and 16C illustrate example reflection responses and latent-space representations of the example nanostructures of FIG. 16A from using the variation of systems 10a and 10b from FIGS. 15A and 15B, respectively.

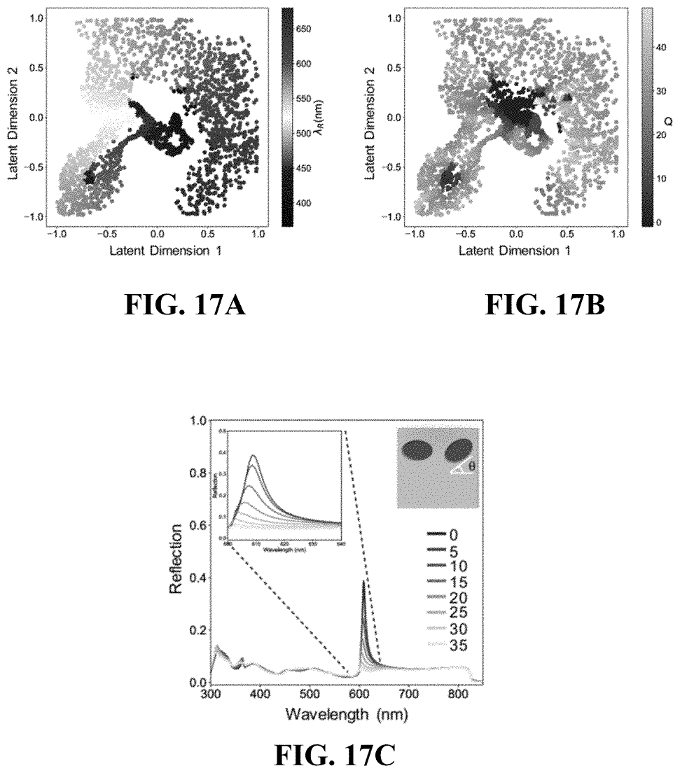

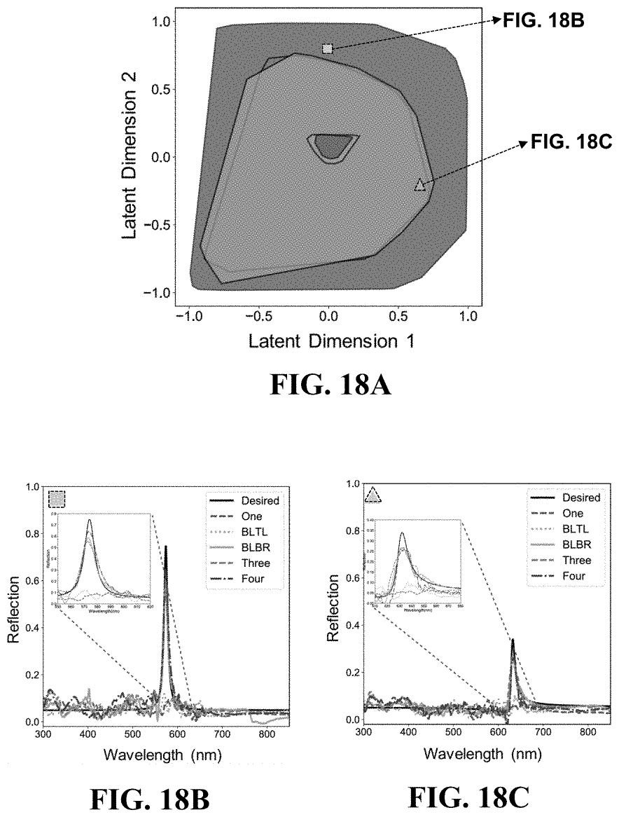

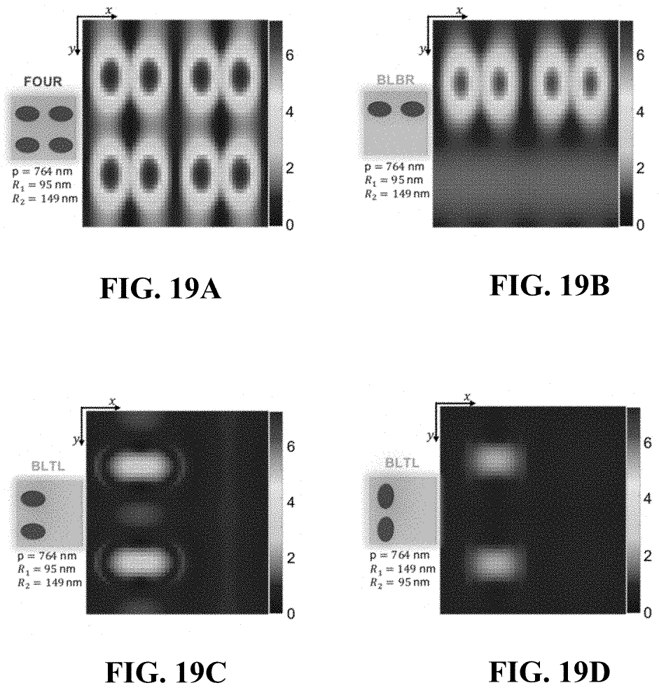

FIGS. 17A-18C provide data relating to the performance of systems 10a and 10b of example nanostructures of FIGS. 12A-12C. FIGS. 19A-19D show nearfield simulation performance data of example nanostructures of FIGS. 12A-12C.

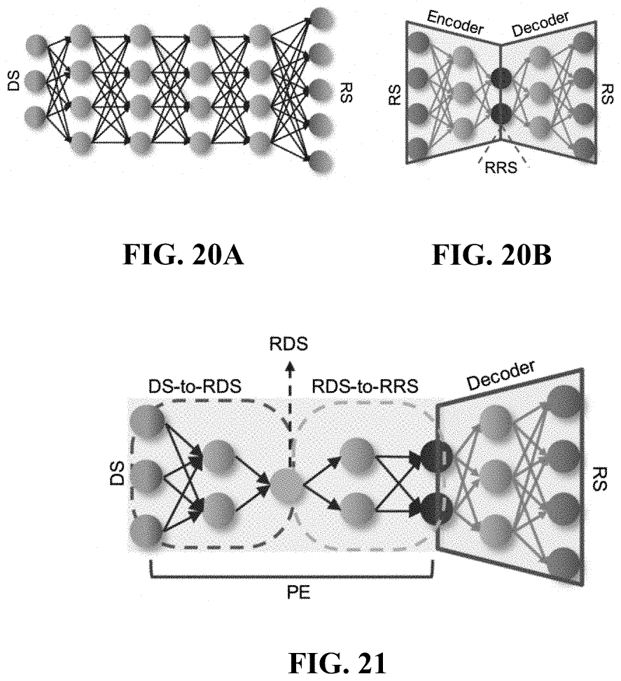

FIGS. 20A-21 illustrate schematics of example neural network variations that can be implemented in systems 10, 10a, and/or 10b.

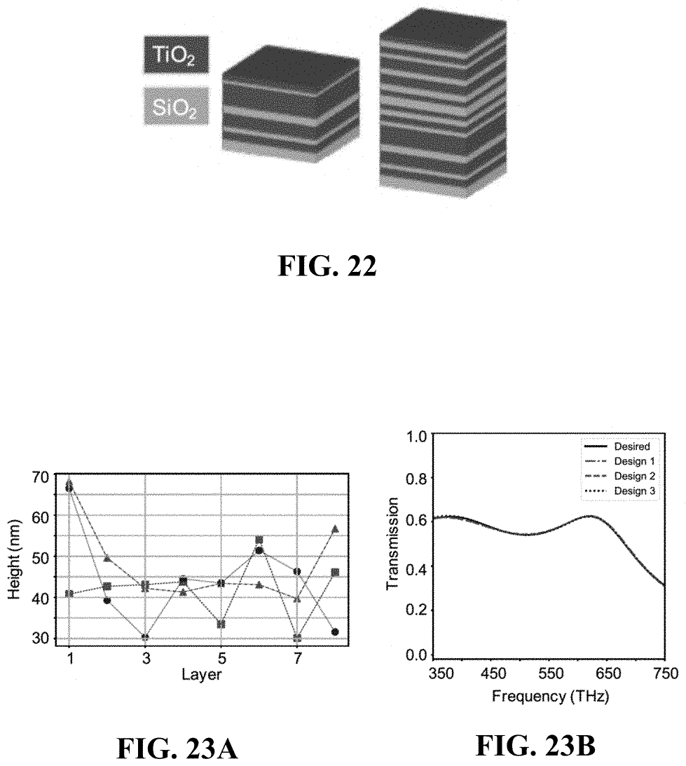

FIG. 22 shows an example schematic of a multi-layer nanostructure, the data of such example design parameters are provided in FIGS. 23A-25B.

The following examples further illustrate aspects of the present disclosure. However, they are in no way a limitation of the teachings or disclosure of the present disclosure as set forth herein.

### EXAMPLES

Photonic nanostructures have been of great recent interest due to their unique capabilities to manipulate the properties of electromagnetic (EM) waves beyond what conventional bulk materials can do. Owing to their constituent nanoscale features, which can spectrally, spatially, or temporally control the optical state of EM waves with subwavelength resolution, nanophotonic devices extend all the functionalities realized by conventional bulky optical devices in much smaller footprints. Combined with the advances in nanofabrication technologies, these nanostructures have been used to demonstrate devices with enormous potential for groundbreaking technologies such as computing, imaging, and energy harvesting, to name a few.

Design of photonic devices in the nanoscale regime outperforming the bulky optical components has been a long-lasting challenge in some state-of-the-art applications. Accordingly, devising a comprehensive model to understand and explain the fundamental physics of light-matter interactions in these nanostructures is a substantial step toward the realization of novel nanophotonic devices. To this end, existing modeling methods can be categorized into two main groups; single- and multi-objective approaches. Single-objective approaches either rely on exhaustive design parameter sweeps using a brute-force EM solver (e.g., based on the finite element method) or evolve from an initial guess to a final result through evolutionary methods (e.g., genetic algorithm). While the former requires extensive computation, the latter highly depends on the initial guess and in most cases converges to a local optimum. Both of these single-objective approaches are computationally demanding and fail when the input-output relation is complex, or the number of desired features for a nanostructure grows. On the other hand, multi-objective methods deal with formation of a model to optimize a certain class of problems. Although these methods are more computationally efficient, obtaining an optimal solution is not guaranteed.

Deep learning (DL)-based design approaches, combined with limited exhaustive searches, have proven to be a potent solver of multi-objective optimization problems by learning the input-output relation. Although DL-based approaches can be applied to nanophotonic design problems, by finding the geometry of the data while reducing the dimensionality of the response and design patterns, they can go much further and provide considerably more information and intuition about the dynamics of light-matter interaction in nanostructures with the hope of uncovering new physical phenomena that can be used to form completely new type of devices. Unfortunately, there has been little effort on using these techniques to obtain detailed knowledge about the physics of light-matter interaction in EM nanostructures (e.g., metasurfaces (MSs)). The change of focus of using DL techniques from “optimization” to “learning” can open a new research area with potentially transformative results in the entire field of nanophotonics. Examples of these “learning” paradigms include assessing the feasibility of a desired response using a given structure as well as the potential of a given structures in providing a range of possible responses. Such information can enable the evolution of the design from an initially selected nanostructure to a considerably simpler and fabricationally favorable structure The focus of this disclosure is to study these feasibility issues in nanostructures while discovering latent optical phenomena.

Knowing the feasibility of a desired response offered by a photonic nanostructure is very helpful prior to any design or optimization effort in avoiding suboptimal designs or convergence issues. It also guides us to modify the initial structure to achieve the desired response. This important concept has not been considered in existing optimization and inverse design approaches, which provides a solution to any inverse design problem regardless of its feasibility.

A geometric deep learning (GDL)-based technique is presented by forming the smallest convex set (i.e., convex hull) to discover hidden optical phenomena while analyzing the feasibility of having a desired optical response from a certain class of EM nanostructures. GDL is a term for techniques aims to generalize DL approaches by considering the non-Euclidean domain such as manifolds. These methods reduce the dimension of the patterns while finding the governing geometry of the patterns in low-dimensional space which Euclidean distance can be a good measure for similarity of the patterns. The developed approach is based on reducing the dimensionality of the response space (RS) of a given EM nanostructure and finding the convex hull that contains achievable responses in the latent RS. The dimensionality reduction (DR) implementation is based on the autoencoder (see Hinton, G. E. & Salakhutdinov, R. R. Reducing the dimensionality of data with neural networks. Science 313, 504-507 (2006)), and the Quickhull (see Barber, C. B., Dobkin, D. P., Dobkin, D. P. & Huhdanpaa, H. The quickhull algorithm for convex hulls. ACM Transactions on Mathematical Software (TOMS) 22, 469-483 (1996)) algorithm is used to form the convex hull in the latent RS. The technique uses the numerical simulation of the response of the system for a series of randomly selected design parameters (called training sets) and another series of similar simulation results for validation of the technique. After initial training and validation, the algorithm finds the optimal bounded subset, which contains all feasible responses. The optimal region that contains the feasible responses might not be convex in many cases, and it is better to also find a tighter bound over feasible responses in the latent RS. For this purpose, the inventors use the one-class support vector machine (SVM) algorithm to find the non-convex geometry. One-class SVM also provides information about the level of feasibility (or non-feasibility) of a response and the possibility of trading an acceptable error (or a small change in the desired response) to get the closest feasible response from a non-feasible one. Despite being implemented for the EM nanostructures (especially dielectric and plasmonic MSs), the disclosed technique can be applied to a wide variety of applications once the training data can be provided. Some example extensions include thermal structures, fluidic systems, mechanical platforms, and acoustic metamaterials.

The rest of the disclosure is organized as follows. Section 2 describes the details of the approach. Section 3 demonstrates the application of the approach to two classes of important MSs. Section 4 is devoted to the comparison of the findings of the disclosed technique with experimental data. It is followed by discussion in Section 5 and conclusion in Section 6.

### Example 1—Theoretical Framework for Studying the Feasibility of a Given Response Convex Hull of a Set of Data Points

The convex hull of a set of points is defined as the smallest convex set that contains all those points. A d-dimensional convex hull can be represented using its vertices and (d-1)-dimensional facets. The ridges of the convex hull are (d-2)-faces, which are the intersection of the vertices in two neighboring facets. There are different algorithms presented in geometrical computation to form the convex hull of a given set of points. One of the most effective and well-known algorithms is Quick-hull, which forms the convex hull using an incremental method based on Grunbaum's Beneath-Beyond theorem (see below). For a typical problem, the Quickhull algorithm starts with a set of given (or training) points and forms the initial convex hull. The points that lie outside the initial convex hull are considered as the outside set. The farthest point from the initial convex hull (i.e., the point with the maximum Euclidean distance from its nearest facet) is found at each iteration and the facets, ridges, and vertices are updated based on Grunbaum's Beneath-Beyond theorem. These steps are repeated until the algorithm converges.

While the convex hull algorithm is capable of finding a convex geometry for feasible responses, it has some limitations. If the optimum feasible region is not convex, inevitably some unfeasible regions in the latent RS will be included in the convex hull to reach a convex region. This limits the efficiency of the algorithm for such structures due to the false-positive errors. Moreover, the algorithm acts as a binary classifier and classifies responses into two classes: feasible (achievable) and unfeasible (unachievable). In most practical cases, it is desirable to know how far an unfeasible response is from feasible responses. It is also helpful to know whether it is possible to push an unfeasible response toward the feasible region by accepting some error. Unfortunately, the Euclidean distance of a given point in the latent RS from the geometry of the convex hull is not a good measure for feasibility of the corresponding response. To address this limitation, the inventors use one-class SVM in the latent RS as the alternative algorithm.

### Example 2—One-Class SVM for a Set of Data Points

One-class SVM is an algorithm that separates the patterns into two regions (e.g., feasible and unfeasible in the example case). In addition, the Euclidean distance between any point in the space and the geometry of the one-class SVM is a good measure of this separation (e.g., a good measure of the feasibility of a response in the example cases disclosed herein). Mathematically, a one-class SVM forms a nonlinear geometry by projecting patterns xᵢ through a nonlinear function ϕ to a higher-dimensional space F. This mapping helps to separate linearly non-separable patterns in the input space I in a high-dimensional space by a hyperplane (represented with w^{T}+b=0, w∈F and b∈R). By projecting this hyperplane from the high-dimensional space back to the original space, the algorithm finds the equivalent non-convex decision geometry. In this projection, the resulting region for the desired (or feasible) class of data may not only have a non-convex geometry, but it may also exclude smaller closed regions within the geometry. The implementation of the one-class SVM has considerable flexibility through two parameters ν and γ which control the tightness of the geometry of the decision region and the maximum ratio of the given training patterns that fall outside the geometry (and thus, contribute to classification error). By using different values of γ, one can find a series of boundaries with different levels of classification errors for the ground-truth data. However one-class SVM shows is capable of finding the non-convex geometry of latent patterns, computation complexity of validating ν and γ in each iteration prevents using it as a prelimenary approach of forming the geometry. Further details about the one-class SVM are provided in Example 9 below.

### Example 3—Investigation of the Feasibility of a Desired Response from a given Structure

FIG. 1A shows the schematic of the disclosed technique for forming the convex geometry of feasible responses of a given nanostructure. In the first step, a full-wave EM simulation software (or alternatively an EM wave solver using an analytic or a semi-analytic model) is used to provide an initial batch of randomly generated patterns (the inventors refer to them as the input dataset). Each pattern is calculated using a given set of randomly selected design parameters (i.e., a point in the design space (DS)), and thus, it relates the DS to the RS. Then, the inventors reduce the dimensionality of the RS by training an autoencoder using a subset of the available training data and a desired autoencoder reconstruction error. Next, the inventors use the Quickhull algorithm to form a convex hull to bound the patterns in the latent RS. Then, the inventors validate the convex hull by using a batch of validation data. Since all of the validation responses originate from a feasible structure, the optimum convex hull should bound all the validation data. We put a threshold for the validation success rate. If the convex hull does not pass the validation step, the validation batch will be added to the initial training batch to expand the training dataset for retraining the algorithm. This process is repeated until the resulting convex geometry reaches the desired validation success rate. After convergence, the convex geometry is tested using an unseen test dataset (that includes both feasible and unfeasible responses) to find its performance defined by the error rate. A similar process is used for training the one-class SVM as shown in FIG. 1B to find the non-convex geometry of feasible response patterns in the latent RS.

### Example 4—Results

To demonstrate the potentials of the disclosed technique, the inventors apply it to the investigation of possible optical reflection responses from plasmonic and dielectric MSs as two popular classes of photonic nanostructures. FIGS. 2A and 2B show two implementations of a digital plasmonic MS consisting a 7×7 and a 14×14 array of binary nanocubes of stacked aluminum/alumina (Al/Al₂O₃), respectively. The significant number of plasmonic inclusions or design parameters, especially that in FIG. 2B, allows these structures to form sophisticated EM responses like Fano and Lorentzian resonances. As an alternative, the inventors also consider a median-index dielectric MS formed by a square lattice array of Hafnia (HfO₂) nanoparticles on a transparent substrate as shown in FIG. 2C. For both classes of MSs, the inventors train a convex hull and a one-class SVM to quantitatively evaluate the practical feasibility of any desired response based on a small set of simulation results found by calculating the reflection spectrum of the MS in the visible wavelength range using the finite element method (FEM) implemented in a commercial full-wave package COMSOL Multiphysics, as explained in the Methods.

The design patterns in each case are achieved by random selection of the binary inclusions, and the calculated reflection spectra are sampled uniformly in the 400-800 nm wavelength range with 2 nm resolution to form a vector with dimensionality of 200 forms the response patterns. Due to the iterative nature of the algorithms in FIG. 1A, the minimum number of training data depends on the number of iterations for convergence. In addition, the inventors use 500 simulated response patterns for testing the algorithms after convergence. Based on several simulations, the inventors chose 8000 as the size of the training/validation data. Knowing that achieving an ideal Fano lineshape is not possible with these structures (due to remarkable Ohmic loss of metals in the visible range), the inventors also formed 80 ideal Fano lineshapes using the Equation S8 as non-feasible responses to test the algorithms.

Table 1. Average distance of different classes of test data (14×14 and 7×7 responses as well as Fano and Lorenzian lineshape resonances) from the highest confident region border for one-class SVM. Distances for random samples represented in the most-right column is also represented. The distances are calculated using Eq. S8.

After obtaining the training dataset, the first step of implementation is the dimensionality reduction of the RS by training an autoencoder. To find the optimum dimensionality of the latent RS and the number of layers of the autoencoder, the inventors use an ad-hoc approach by using different structures and dimensionalities and calculating the mean squared error (MSE) for each case. The details of this approach are explained in Kiarashinejad, Y., Abdollahramezani, S., Zandehshahvar, M., Hemmatyar, O. & Adibi, A. Deep learning reveals underlying physics of light-matter interactions in nanophotonic devices. Advanced Theory and Simulations (2019). FIG. 3A shows the variation of the MSE of the autoencoder trained for the 14×14 array in FIG. 2A with the dimensionality of the latent RS. The autoencoder in each case is trained and tested with 8000 and 2000 random response patterns, respectively. FIG. 3A suggests that using 6 as the dimensionality of the latent RS results in MSE of 0.001, which can be translated to less than 5% point-to-point error (see Example 10 below). To find the optimum convex hull in the resulting latent RS, the inventors start with an initial batch of data with 5000 ground-truth patterns in the algorithm in FIG. 1A with the trained autoencoder with dimensionality 6 to train the autoencoder and forming the convex hull in 6-dimensional space. At each iteration, the inventors use 200 validation data for autoencoder and 200 for convex hull. We select 0.001 (5% point-to-point error) for the autoencoder validation threshold and 95% for in-point percentage, respectively. The algorithm converged after 14 iterations. As a result, the inventors used 11000 data to reach convergence. FIG. 3B shows the MSE of the autoencoder and percentage of ground truth test data that lie in the convex hull for each iteration respectively. After validating the convex hull and its corresponding autoencoder, the inventors feed test data consisting of feasible responses for the 14×14 and 7×7 binary nanostructures as well as non-feasible idea Fano resonances to the algorithm. The results (see Table 2) show that about 91.8% of the feasible responses of the 14×14 structures, 96% of those of the 7×7 structures, and none of the Fano resonances are enclosed by the convex hull. To provide a visual prospective of the convex hull, the inventors repeat the algorithm in FIG. 1A in two-dimensional (2D) and three-dimensional (3D) latent RS (dimensionality of the response RS being 2 and 3, respectively). We set 0.005 and 0.0035 as the autoencoder validation error (10% and 7% point to point error) for 2D and 3D spaces, respectively, while using 95% as the in-point percentage threshold for both spaces. FIGS. 4A and 4B show the converged convex hulls in 2D and 3D reduces RSs; the calculated errors in testing the resulting convex hulls are shown in Table 2. It is clear from Table 2 that both 2D and 3D algorithms are capable of identifying the feasible responses with better than 99% accuracy, but their ability in identifying the non-feasible responses are reduced (from 0% to 3.75% and 48.75%, respectively). In other words, by reducing the dimensions, it seems that the convex hull covers a larger percentage of the overall area of the RS resulting in a larger error in identifying the non-feasible responses.

TABLE 2
In-points percentage of each class of test patterns (14 × 14 and 7 × 7
responses as well as Fano line-shape resonances) lies in the 2-D, 3-D, and
6-D convex hull as well as one-class SVM highest confidence region.

| Algorithm; Class | Binary 14 × 14 | Binary 7 × 7 | Fano line-shapes |
|---|---|---|---|
| Convex 2-D | 99.8% | 99.8% | 48.75% |
| Convex 3-D | 99% | 99.6% | 3.75% |
| Convex 6-D | 91.8% | 96% | 0% |
| One-class SVM 2-D | 90.8% | 91.6% | 0% |
| One-class SVM 3-D | 92.4% | 87.6% | 0% |
| One-class SVM 6-D | 88.2% | 84.8% | 0% |

TABLE 3
In-points percentage of each class of test patterns (simulation and
experimental data) lies in the 2-D and 3-D convex hull as well as
one-class SVM highest confidence region.

| Algorithm; Class | Simulation | Experiment |
|---|---|---|
| Convex 2-D | 100% | 93.9% |
| Convex 3-D | 98% | 84.8% |
| One-class SVM 2-D | 91.5% | 84.8% |
| One-class SVM 3-D | 93.5% | 87.8% |

TABLE 4
Average distance of test patterns for the responses achieved from
nanopillars to the formed geometry of one-class SVM (using the
training data achieved from the simulation patterns).

| Algorithm; Type | Simulation | Experiment |
|---|---|---|
| One-class SVM 2-D | 2.4851 | 2.2079 |
| One-class SVM 3-D | 3.1844 | 2.9742 |

It is important to note that despite training with a non-aggressive success rate of 95%, the convex hull algorithm is capable of identifying all non-feasible responses as well as a large portion of the feasible responses. Nevertheless, the convex hulls in FIGS. 4A and 4B do not provide the level of feasibility or non-feasibility of a response. For example, it is not trivial to compare the robustness of the resulting designs for achieving two responses as there is not a simple one-to-one relation between the distance to the convex hull geometry and the feasibility of a response. To add this feature, the inventors use the same training/validation data to train a one-class SVM to find the non-convex geometry of the feasible responses for the structure in FIG. 1A using 6D, 3D, and 2D latent RSs. While one-class SVM provides valuable information about the relative feasibility of each desired response, finding the optimum hyper-parameters (i.e., ν and γ) for one-class SVM is challenging. Here the inventors use 500 validation patterns and find ν=0.4 and γ=0 as the optimum hyper-parameters. Table 2 shows the results of testing the six dimensional (6D), 3D, and 2D one-class SVMs algorithm with the same data used for testing the convex hull algorithm. Smaller success rates in identifying the feasible responses while perfect performance in identifying non-feasible responses are attributed to the tighter (non-convex) geometry of the one-class SVM. This is also seen from the graphical representation of the one-class SVM in the 2D latent RS in FIG. 4C. Note also that the absolute value of the success rates in Table 2 for class-one SVM depend on the definition of the highest confidence region. Reducing the level of confidence results in extension of its corresponding geometry and thus, a smaller error. In addition to the innermost geometry (also known as the highest confidence geometry) shown by the curve red in FIG. 4C, several boundaries are identified with different colors.

Each added region corresponds to a different level of non-feasibility of a response that lies outside the highest confidence region. A quantitative measure for the level of feasibility of a response in this one-class SVM is the minimum distance of that response form the geometry of the highest confidence region. The calculated distance in a 6D one-class SVM for a series of responses of the structure in FIG. 1A are shown in Table 1. The average distance for each class of calculated responses in Table 1 is calculated over the entire set of those responses in the test dataset. In addition, for each class, a representative sample response and its actual distance from the geometry is shown. A negative (positive) distance shows that the point lies outside (inside) the highest confidence region; the absolute value of the distance shows the relative non-feasibility (feasibility) of a response. Table 1 clearly shows that a smoother response (e.g., the first row of Table 1) has a better feasibility than a sharper one (second row of Table 1). It also confirms the non-feasibility of the ideas Fano and Lorentzian responses with Fano responses being farther from the feasibility region.

### Example 5—Experimental Results

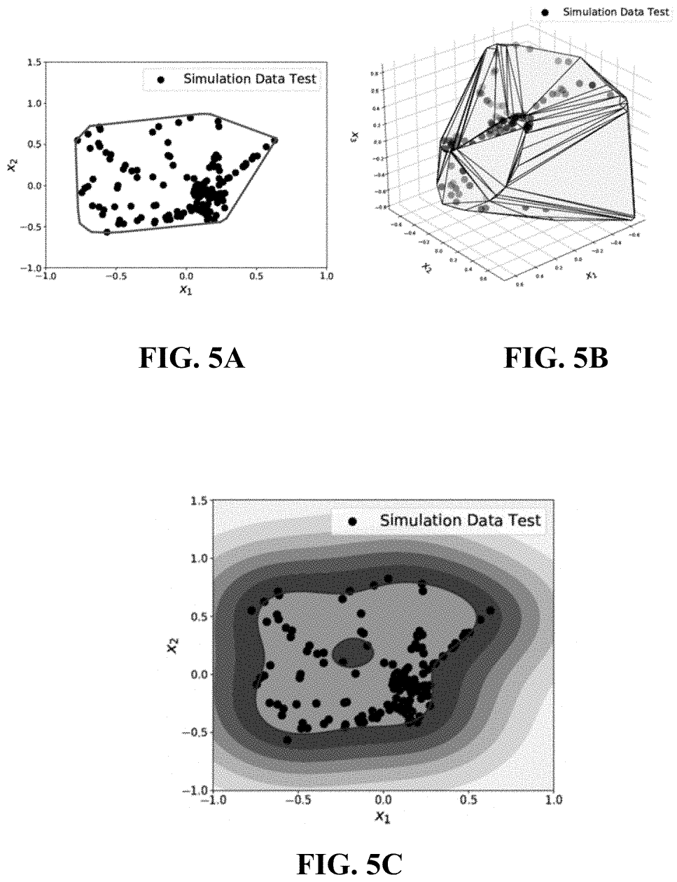

To show the applicability of the disclosed technique in practical problems, without loss of generality, the inventors choose the reflective structure of a low-loss dielectric MS, which can be experimentally fabricated and characterized. FIG. 2C shows the MS which is formed by a 2D periodic array of Hafnia (HfO₂) nanopillars. The training data for this structure is found by simulating the constituent unit cell with different geometrical parameters using FEM implemented in the COMSOL Multiphysics (see Methods section). The dimensions of the unit cell (pₓ and p_{y} in FIG. 2C) can be changed between 250 nm to 450 nm while the radii of the nanopillars are proportionally modified from r_{x,y}=0.6 p_{x,y} to r_{x,y}=0.75 p_{x,y}. The structure is illuminated by a TM-polarized plane wave of light at normal incidence, and the reflection coefficients at the far-field are calculated over the range of 400-800 nm wavelength range for 2400 patterns. The reflection spectra are uniformly sampled at 200 wavelengths to form a 200-dimensional RS. The resulting data is used to form the convex hull and one-class SVM of the MS using the algorithms in FIG. 1. The convex hull-forming algorithm starts with an initial batch of data of 1000 patterns to train the autoencoder and form the convex hull in 2D and 3D. In each iteration, the inventors use 200 validation data for the autoencoder and 200 for the convex hull. We select 5% and 95% as the validation thresholds for the autoencoder MSE and in-point percentages for the convex hull, respectively. The algorithm converges after 5 (7) iterations for 2D (3D) RS space. After convergence, the inventors test the algorithm using 200 ground-truth patterns whose results are shown in FIGS. 5A and 5B. We also train a one-class SVM with ν=0.4 and γ=0.1, and the results are depicted in FIG. 5C. Our calculated inpoints rate for the 2D (3D) convex hull and the one-all SVM over the entire test data is 100% (98%) and 91.5% (93.5%), respectively.

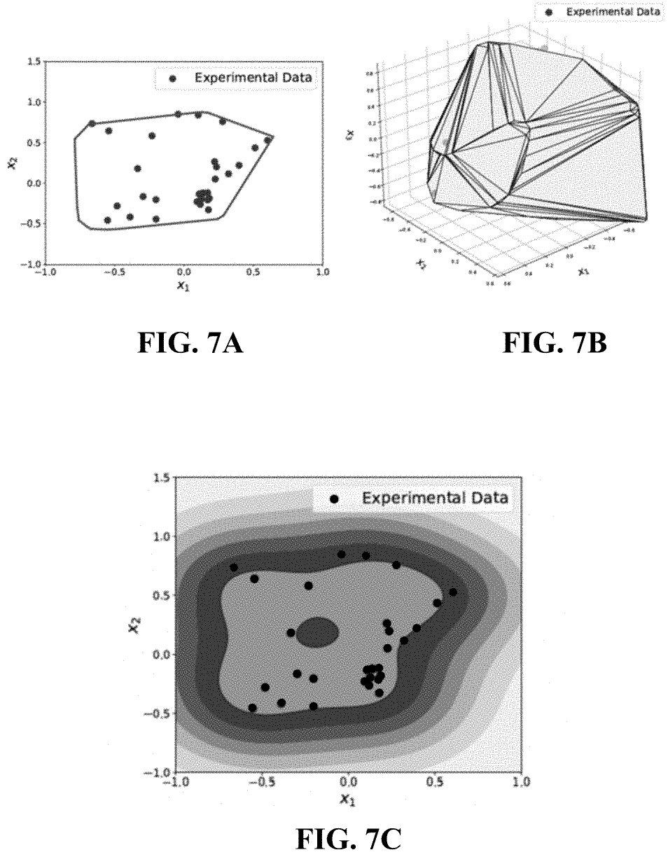

To evaluate the convex hull experimentally, the inventors fabricated dielectric MSs with symmetric unit cells (i.e., pₓ=p_{y}=p) with 250 nm<p<450 nm consisting of symmetric nanopillars (i.e., rₓ=r_{y}=r) with 0.65 p<r<0.75 p (see Example 7 below). The scanning electron microscopy (SEM) image for the fabricated MS with p=450 nm and r=0.75 p is shown in FIG. 6A. Moreover, FIG. 6B shows a good match between the simulated and measured reflectance spectra which validates the accuracy of the disclosed experimental approach. FIGS. 7A-7C show the placement of the experimentally measured response in the RS space of the structure. It is clear that a large portion of the feasible responses fall within the convex hull and the one-class SVM. In addition, the responses that fall outside the one-class SVM are close to the geometry of the highest confidence geometry with small distances. The calculated success rates of the 2D (3D) convex hull and the one-class SVM in FIGS. 7A-7C for the experimental results is 96% (98%) and 90% (92%), respectively, which is in good agreement with the theoretical results. Note that the despite using low dimensions for the latent RS, the disclosed techniques provides good success rates in identifying the feasible responses.

### Example 6—Discussion

The results in previous sections clearly show the power of GDL algorithm in assessing the feasibility of a desired response given a specific nanostructure design. They also show the advantage of one-class SVMs in providing a more quantitative measure for the feasibility of the desired response. This advantage comes from the fact that in one-class SVM, the geometric distance of a point in the latent RS from the geometry of the one-class SVM is a good gauge for the feasibility of the structure while in general convex hulls, this relation does not hold. This advantage comes at the expense of more sophisticated training as the optimum hyper-parameters ν and γ in SVM are not usually trivial to find. In practice, the inventors first find the convex hull of the feasible responses, and use it to find proper values of ν and γ. Nevertheless, convex hulls are helpful in providing quick evaluations of the feasible responses. The training process can also be simplified if more error is accepted. Note also that finding the actual geometry of the convex hull and one-class SVM may not be important in design and optimization problems as the points on the boundaries are less reliable to be feasible. We prefer the desired response to be in the middle of one-class SVM.

In addition to the boundaries of convex hull and one-class SVM in the latent RS, the area that is covered in that space by these shapes has important practical implications. The larger the area, the more capable the structure is in forming output responses. FIGS. 4A and 4B show convex hull and one-class SVM, respectively, in the 2D latent RS of the binary MS structure in FIG. 2A formed by 7×7 array of pixels. For comparison, the responses used for the training of the 14×14 structure in FIG. 2B is also provided.

FIG. 4C shows the 2D convex hull and one-class SVM, respectively, for the 14×14 structure while the training data for the 7×7 structure also presented. It is clear from FIGS. 4A and 4B that the convex hull and one-class SVM of the 7×7 structure cover a smaller per-centage of the 2D latent RS than those of the 16×16 structure. This conclusion must be taken with the caveat that the latent RSs for the two structures are not necessarily the same. FIGS. 4A-4C clearly show that while technically none of the responses of the 7×7 structure was used in training the convex hull and one-class SVM of the 16×16 structure, all these responses fall inside the convex hull and one-class SVM as any 7×7 structure can be formed using the 14×14 structure. FIGS. 4A and 4B also show that some of the responses achieved by the 14×14 structure cannot be achieved using the 7×7 structure while some of them can. This is an important observation as it confirms that using the 16×16 structure for some responses might be unnecessary; the same response can be achieved by a much simpler structure with less fabrication challenges and more robustness against fabrication imperfection. We believe this observation is an important potential application of convex hull and one-class SVM in finding the most robust and least complex structures when starting from a non-optimal design. In addition, selecting a structure for which the desired response falls in the middle of the one-class SVM (i.e., has maximum distance from the boundaries) results in more tolerance against environmental changes and fabrication imperfections.

Note that the dimensionality reduction algorithm implemented by the autoencoder is an important step in reducing the computing requirements for the convex hull and one-class SVM. For any particular problem, the optimum dimension of the latent RS depends on the selection of the design and the redundancy of the response (i.e., the level of non-uniqueness). Thus, finding the optimum size of the latent RS is the initial step in implementing the algorithms of this disclosure. Once the size of the latent RS is selected, the required computation for the calculation of the convex hull and one-class SVM are primarily for the training algorithm. In this disclosure, the inventors mainly used the brute-force approach in starting with a training dataset and expanding it until the convex hull (and subsequently the one-class SVM) pass the validation test. Further rigorous approaches muse be developed to minimize the computation for training. One can also take advantage of the trade0off between the accuracy (or the error) and the computation requirement as explained above.

Although the focus of this disclosure was the first demonstration of a GDL-based technique for studying the feasibility of a given response, this technique can be adopted for obtaining far more detailed information about the physics of nanostructures. As an example, FIG. 4C clearly shows that the Fano-type resonances are clustered separately from the non-Fano-resonances. Further extension of this technique to separate more classes of responses (known as clustered homotops) is currently under investigation.

### Example 7—Methods

Numerical Simulations. All numerical simulations throughout this disclosure were carried out in COMSOL Multiphysics commercial software interfaced to MATLAB to facilitate the process. For the design of unit elements, periodic geometry conditions and perfectly match layers were considered in the lateral and vertical directions, respectively. A TM-polarized light in the range of 400-800 nm is launched into the simulation domain, and the co-polarized reflection coefficient was calculated at the location of the input port. The optical constants of Al, Al₂O₃ in FIGS. 2A and 2B were obtained from Palik, E. D. Handbook of optical constants of solids, vol. 3 (Academic press, 1998) using tabulated dielectric functions. The measured ellipsometry data for HfO₂ and quartz were used to simulate the structure in FIG. 2C.

Fabrication process. The dielectric MS shown in FIG. 6A was fabricated on top of a quartz substrate. First, the substrate was cleaned and exposed to oxygen plasma followed by spin coating of the positive-tone e-beam resist (ZEP-520A). The substrate was then soft-baked and coated with a conductive layer of Espacer to prevent charging effects during the writing process. Then, the sample was exposed to the electron beam (ELS-G100) to write the patterns followed by development in the diluted amyl acetate liquid. Atomic layer deposition of HfO₂ was performed using a standard two-pulse system of water and TEMAH at 90° under continuous flow of nitrogen carrier gas (Cambridge Nanotechnology). In the next step, the deposited top HfO₂ layer was etched using inductively coupled plasma reactive ion etching process to reach the top surface of nanostructures. Finally, the sample was exposed to the ultraviolet light and oxygen plasma and soaked in the 1165 remover to remove the residue of e-beam resist.

### Example 8—Convexity and Convex Hull

Having a set of points, there are different ways to find a boundary that bounds these points like Simplex, Voronoi Diagram, Convex hull, etc. The convex hull of a set of points is the smallest convex set that contains the points. Considering x₁, x₂, . . . , xₖ∈X, the convex combination of these points is defined as θ₁x₁+θ₂x₂+ . . . +θₖxₖ where θᵢ≥0 and θ₁+θ2+ . . . +θₖ=1. A set is convex if and only if it contains all the convex combination of its points. The convex hull of the set of points, X, is denoted as conv X and is defined as:

conv X={θ₁x₁+θ₂x₂+ . . . +θₖxₖ|xᵢ∈X, θᵢ≥0, i=1, 2, . . . , k, θ₁+θ₂+ . . . +θₖ} (S1)

Considering the convex hull operator on a set of points, it is (1) Extensive (i.e. Convex hull of all sets in X is a superset of X), (2) Non-decreasing (i.e. convex hull of a subset of set X, is a subset of convex hull of X), and (3) Idempotent(i.e. Convex hull of the convex hull of X is same as convex hull of X). The convex hull of any set of points is also unique and closed set.

There are different algorithms presented in Geometrical Computation to form the convex hull of a given set of points. One of the most effective and well-known algorithms is Quickhull. This algorithms find the convex hull of a set of points in d dimension using an effective method both in memory and computation. Given a set of n data points with r processed point, the algorithm is O(nlogr) if the dimension of the convex hull is less than or equal to 3 and is O(nfᵣ/r) for d being more than 3 (fᵣ is the maximum number of facets for r vertices). Let's define extreme points of a convex hull as those points that are vertices of the boundary of the convex hull. The running time of the, algorithm as mentioned, will be output dependent since it depends on the number of facets and vertices. Therefore, for those sets that the inventors have less extreme points, it takes less time for the algorithm to find the solution. A d-dimensional convex hull can be shown using its vertices and (d-1)-dimensional faces. The ridges of the convex hull are (d-2)-faces which are the intersection of the vertices in two neighboring facets. Quickhull forms the convex hull using an incremental method. First consider the Grunbaum's Beneath-Beyond theorem is used in this incremental algorithm.

Consider H as the convex hull of a set of points in R^{d} and a point p in R^{d}−H. F is a facet of conv(HUp) if and only if:

(1) F is a facet of H and p is below F, or

(2) F is not a facet of H. and its vertices are p and the vertices of a ridge of H that has one incident facet below p and one above p.

The quickhull algorithm starts with a set of points (i.e., a random subset of all datapoints) and forms the initial convex hull. All the points that lies outside of the initial convex hull are considered as the outside set. The furthest point from the outside set is found at each iteration and based on theorem 1, the facest, ridges, and vertices will be updated. This process will continue until convergence. The resulting convex hull consists all the datapoints. The random based methods, however, consider a random point from outside set at each iteration. This makes the process time consuming and the running time of the algorithm will be much more than quickhull.

After forming the convex hull for set X in the space, the inventors need to find out whether a given point p lies inside the convex hull or not. First consider one random point a outside of the convex hull. Then connect x and a with a line segment. Find the number of intersection of the line xa and every vertex of the convex hull. If the number of intersections is odd, the point lies inside the convex hull. Otherwise, if the number of intersections is even or zero, this point is outside the convex hull.

### Example 9—One-Class SVM

As discussed before, the convex hull method just provides us binary decisions about the feasibility of the responses. To tackle this limitation, one-class SVM is used. Assume that the training data are x₁, x₂, . . . , x_{N}∈X where N is the number of datapoints. Considering the mapping ϕ(x) from feature space, X, to a dot product space F, the kernel function is defined as:

k(xᵢ, xⱼ)=(ϕ(xᵢ), ϕ(xⱼ)) (S2)

There are different choices for the kernel function like Gaussian and polynomial kernel. In this research, the inventors used the Gaussian kernel.

$$k ( x , y ) = {e}^{- \frac{{‖ x - y ‖}_{2}^{2}}{2}} \qquad ( S3 )$$

One-class SVM then can be formulated as an optimization problem which finds a hyperplane to separate datapoints in X from the origin in F and has the maximum distance from the origin. This problem is formulated as a quadratic program:

$${min}_{w ∈ P , ξ ∈ {R}^{N} , ρ ∈ R} \frac{1}{2} {‖ w ‖}_{2}^{2} + \frac{1}{vN} {\sum }_{i = 1}^{N} {ξ}_{i} - ρ \\ s . t . 〈 w , ϕ ( {x}_{i} ) 〉 \geq ρ - {ξ}_{i} ∀ i ∈ \{ 1 , … , N \} \\ ξ \geq 0 \qquad ( S4 )$$

Here ν∈(0, 1] is a free parameter of the algorithm. The slack variables ξᵢ let the algorithm to misclassify some points to have a better generalization over unseen datapoints. Therefore, the free parameter ν penalizes the number of misclassified points. For ν=0, the penalty for the slack variables is infinity and all the algorithm will overfit to the training data while for larger ν more slack variables can have non zero value and the algorithm underfits. It is more practical to solve the dual problem for one-class SVM.

$${min}_{a ∈ {R}^{N}} \frac{1}{2} {Σ}_{ij} {α}_{i} {α}_{j} k ( {x}_{i} , {x}_{j} ) \\ s . t . 0 \leq {α}_{i} \leq \frac{1}{vN} ∀ i ∈ \{ 1 , … , N \} \\ {Σ}_{i} {α}_{i} = 1 \qquad ( S5 )$$

By solving this optimization problem, which is a quadratic programming, the decision function becomes:

$$f ( x ) = {\sum }_{i} {α}_{i} k ( {x}_{i} , x ) - ρ \qquad ( S6 )$$

Here p can be recovered using the dual variables. Those datapoints xᵢ that the optimized value αᵢ is non-zero are called support vectors. These datapoints are mainly close to the boundary and enforces the complexity of the boundary.

### Example 10—Dimensionality Reduction

The dimension of the original response space is 200. This high dimensional space results in two major issues that should be solved. First, due to the curse of dimensionality the distances and patterns in high dimensional space cannot be interpreted and results in low performance. Second, running time of the Quickhull algorithm increases as the dimensionality increase and forming the convex hull in such high dimensional space is not practical. To address these problems the inventors used auto-encoder to reduce the dimensionality of the response space. We reduce the dimensionality to 2D and 3D for visualization. However, to find the optimum dimensionality, the inventors need to find the reconstruction error. The MSE is shown in FIGS. 10A and 10B. As described above, an Inhull function finds points inside and outside of the convex hull by finding the number of intersections of the line between a sample point (for instance, x in FIG. 10A) and a random point (a) outside of the convex hull. As shown in FIG. 10A, when the number of intersections of line xa is even, then point x is outside the convex hull. Alternatively, when the number of intersections of line xa is odd, then point xis inside the convex hull, as shown in FIG. 10B.

To have a better sense of the efficiency of the algorithm, the inventors define point-to-point error (Errorₚ). Assume that the inventors have n response patterns and each response pattern achieved by discretizing the response by measuring reflectance (r and \dot{r} represent ground truth and estimated reflectance respectively) in m different wavelengths (i.e λ). The point-to-point error becomes:

$${Error}_{p} = 1 \text{/} mn {\sum }_{j}^{n} {\sum }_{i}^{m} \frac{\vert {r}_{i} ( {λ}_{j} ) - \hat{{r}_{i}} ( {λ}_{j} ) \vert}{\vert {r}_{i} ( {λ}_{j} ) \vert} \qquad ( S7 )$$

### Example 11—Results for Plasmonic Oligomer

FIGS. 10A and 10B show the results in 2D for the plasmonic oligomer. As it is shown, this structure has some sharp resonances which is not likely for the 14×14 binary structure. Considering the physical properties of the 14×14 binary structure, the responses with sharper resonances (e.g. 1, 2, 12, 10) have more distance to the feasible region and are less likely. On the other hand, the smoother responses (e.g. 7, 8, 9) that do not have sharp Fano-type resonances are more likely and has less distance to the feasible region.

### Example 12—Fano-Lineshapes

To understand the capabilities and limitations of the binary structures, the inventors tested the algorithm with Fano-lineshapes. These type of resonances can be observed in the reflectance response of the all-dielectric MS consisting of HfO₂ NPs shown in FIG. 2C in the main text, or in the scattering response from the plasmonic oligomers shown in FIGS. 12A-12C. In the former case, the reason for appearance of sharp Fano resonances are the strong coupling between the directly reflected light and the local magnetic dipole mode inside the NPs. On the other hand, for the latter case, the destructive interference between two subradiant and super-radiant modes supported by the nanoclusters result in a dip in the scattering spectrum at the Fano frequency. Here, to introduce these types of Fano resonances to the disclosed algorithm, the inventors use the following standard Fano-formula:

$$R = a + ( b + ic ) \frac{γ}{i ( ω - {ω}_{0} ) + γ} \qquad ( S8 )$$

where a, b, and c are the constant real numbers, ω₀ is the central resonant frequency, and γ is the overall damping rate of the resonance. The Q is calculated by Q=ω₀/γ. FIG. 12D represents different types of Fano-lineshapes which both all-dielectric MS consisting of HfO₂ NPs (FIG. 2C), and plasmonic oligomers (FIGS. 12A-12C) can show in their reflectance and scattering responses, respectively.

TABLE 5
Details for the trained auto-encoder

| Activation Function | Tangent Hyperbolic |
|---|---|
| Training Data Division | mini-batches (batch size = 200) |
| Optimizer | Adam |
| Loss Function | MSE |

### Example 13—Workflow of a Manifold-Learning-Based Design Approach

FIG. 15A provides a system and method for forming the feasible regions and learning sub-manifolds in the latent space. Each sub-manifold corresponds to one of the five nanostructure classes, whose unit cells are shown. Random sets of design parameters are generated for each class, and the corresponding responses are found using an electromagnetic (EM) solver. By training an AE, the dimensionality of the response space is reduced into 2 or 3 and each sub-manifold is modeled using a separate Gaussian mixture model (GMM). Each GMM covers the range of feasible responses from a given class of nanostructures. FIG. 15B shows that for inverse design, the dimensionality of the desired response is reduced using the trained AE to observe the feasibility of the response using different classes of nanostructures in a. Using a trained neural network (NN) that relates the design space into the latent response space, the inventors search for the optimum solution with minimal complexity. It is observed from simulations that the reflection responses have a single resonance peak with a Fano-like lineshape as shown in FIGS. 15A and 15B.

### Example 14—Dielectric Metasurfaces with Resonant Reflection Responses

To show the capabilities of the disclosed approach, the inverse design of metasurfaces was studied with reflection responses of Fano-like lineshape using the unit-cell structures shown in FIG. 16A. These structures are composed of a series (one to four) ellipsoids of HfO₂ on a SiO₂ substrate. The design parameters are periodicity (p∈[500;900] nm) and the radii of the ellipsoids (Rᵢ∈[45;200] nm). The height of the ellipsoids (350 nm) is fixed due to fabrication limitations, and the substrate is assumed to be infinite in thickness. The simplest design (ONE in FIG. 16A) and the most complex one (FOUR) have 3 and 9 design parameters, respectively.

For the AI analysis, a total of 8000 random sets of design parameters for the five unit-cell structures are generated, and the corresponding reflection responses are computed using three-dimensional finite-difference time-domain (3D FDTD) simulations, implemented using Lumerical, in the 300<λ<850 nm range, where λ is the wavelength. The incident beam is a normally-incident plane-wave from the top with linear polarization in the x direction in FIGS. 15A and 16A. Each reflection response is sampled at 551 uniformly-placed wavelengths in the operating range. This structure is capable of generating Fano-type reflection responses. Also, when co-polarized resonances of different ellipsoids are strongly coupled in the polarization direction (i.e., x-direction in FIG. 16A), overall resonant responses with relatively high-quality factors (Qs) are observed.

### Example 15—Knowledge Discovery using the Latent-Space Representation of the Reflection Responses

To form the feasible set of responses for each nanostructure in FIG. 16A, an AE is trained to reduce the dimensionality of the response space from 550 (i.e., the number of samples in the spectral response) into two or three (i.e., two-dimensional (2D) and three-dimensional (3D) latent spaces, respectively), while minimizing the reconstructed mean-squared error (MSE). In addition, a convex-hull is trained to encompass the range of feasible responses using each of the unit-cell structures in FIG. 16A, using the system and methods described above. FIGS. 16B and 16C show the representation of the responses and the convex-hulls of the feasible regions for each structure in a 2D latent space, respectively. As seen from FIGS. 16B and 16C, the range of feasible responses expands as the inventors increase the design complexity (i.e., the number of ellipsoids in the unit cell). The feasible region of the structure with one ellipsoid (i.e., ONE) is the smallest due to both the weak resonance in the nano-antenna and weak coupling between the nano-antennas in the periodic metasurface. An interesting observation from FIG. 16C is the large disparity between the convex-hulls of the BLTL and BLBR structures while both having two ellipsoids in their unit cell. Also, the convex-hulls of the BLBR and THREE structures share similar regions despite having different levels of complexity. These non-trivial observations need to be understood using the physics of coupling between different ellipsoids (or meta-atoms).

The latent-space representation of the responses (see FIG. 16A) provides important information about the underlying patterns in the reflection responses. For example, it is observed that the clockwise movement around the feasible region results in a red shift, and the counter-clockwise movement results in a blue shift of the resonances. In addition, FIG. 16B shows an increase in the magnitude and Q of the reflection as the inventors move from the center of the latent space towards the edges. To better quantify the knowledge provided by the manifold-learning approach, the color-coded manifolds are presented for the wavelength and the Q of the Fano-type resonances of the reflection resonances in FIGS. 17A and 17B, respectively. FIG. 17A shows the red (blue) shifts of the resonance wavelength by clockwise (counterclockwise) movements in the latent space, and FIG. 17B shows that higher Qs are achieved at the corners of the latent space.

Comparing the feasible responses of structures with different unit cells in FIGS. 16B, 16C, 17A, and 17B suggests that: 1) the ONE and BLTL structures cannot generate high-Q responses, 2) the BLBR structure is far more capable than the BLTL structure in forming a variety of different responses despite apparent similarity; 3) The BLBR and THREE structures have a similar capability in generating high-Q responses despite their different levels of design complexity; and 4) the FOUR structure provides the largest range of responses thanks to its highest level of complexity. While some of these conclusions (e.g., 4) might be trivial at the beginning, others (e.g., 2 and 3) are not expected at the first glance. This clearly shows the power of the disclosed manifold-learning approach in knowledge discovery in nanophotonics. In addition to comparing different structures with different levels of complexities, the disclosed manifold-learning approach can provide valuable insight about the roles of different design parameters. To show this capability, the inventors study the effect of rotating one of the ellipsoids in the BLBR structure (as the least complex structure with a large range of high-Q responses) on the reflection response while keeping other design parameters fixed (see FIG. 17C). It is clear from FIG. 17C that by rotating one of the ellipsoids (i.e., increasing q from 0), both the peak reflection magnitude and the Q decrease with a minor resonance wavelength shift, however, the reflection response outside the resonance range stays almost the same. To see this in the latent space, the corresponding responses, after dimensionality reduction, have been shown in FIG. 17B using triangles with the same colors as those of the actual responses in FIG. 17C. The movement of these triangles towards the center of the latent space and the lack of considerable clockwise or counterclockwise rotation by increasing q in FIG. 17B confirms the ability of the manifold-learning approach in uncovering the observed role of q. The amount of visually observable information about different classes of unit cells shows the efficacy of the disclosed manifold-learning approach in knowledge discovery, i.e., providing valuable observable insight about the physics of nanophotonic device operation.

### Example 16—Inverse Design using the Manifold-Learning Approach

To better quantify the effectiveness of each unit-cell structure in FIG. 16A in forming a desired response, the sub-manifolds of the corresponding responses was modeled in the latent space for each structure using GMMs (see Example 17 below). These GMMs provide the levels of feasibility of achieving any given reflection response for metasurfaces with different unit-cell structures in FIG. 16A, which will be helpful in the inverse design.

To find a structure that generates a desired reflection response, the first step is to find the corresponding point in the latent space by reducing the dimensionality of the desired response using the trained AE (see the two examples in FIG. 18A). Next, the inventors find the log-likelihood of the feasibility for the desired response using the five different unit cells in FIG. 16A by employing their corresponding GMMs. We select the unit-cell structure with the highest log-likelihoods. Once the unit-cell of the metasurface is selected, the inventors use exhaustive search with a separately trained neural network for the forward problem (i.e., connecting the design and response spaces) of that metasurface to find the optimum design parameters. FIGS. 18A-18C show the implementation of the inverse design problem for two desired responses with high and moderate Qs (see FIGS. 18B and 18C, respectively). To compare the effectiveness of metasurfaces with different unit cells and the importance of the GMMs, the inventors implement each design using all possible unit cells (regardless of the design feasibility), and the corresponding results are shown in FIGS. 18B and 18C as well as Tables 6 and 7, respectively. This experiment mimics the conventional design approaches focused on finding the design parameters regardless of the feasibility of the response. FIG. 18A suggests that the desired response with Q=52 can only be generated using the FOUR structure. This is confirmed by comparing the actual optimal responses (see FIG. 18B) and the negative log-likelihood values (−log(p) in Table 6). Similarly, FIG. 18A suggests that the response with Q=42 can be generated by BLBR, THREE, and FOUR structures. This is confirmed by different optimal responses and log-likelihoods from FIG. 18C and Table 7, respectively. Tables 6 and 7 also provide means for using a trade-off between design complexity and the response errors. The importance of the manifold-learning approach is that it enables the consideration of the feasibility before attempting to design a device using a pre-selected structure.

TABLE 6
Example design parameters (in nm), normalized MSE (NMSE),
negative log-likelihood, for the Fano-reflection response in FIG. 18B.
Design Parameters

| Structure | p | R1BL | R2BL | R1BR | R2BR | R1TL | R2TL | R1TR | R2TR | NMSE | −log(p) |
|---|---|---|---|---|---|---|---|---|---|---|---|
| One | 783 | 178 | 17 | 0 | 0 | 0 | 0 | 0 | 0 | 0.60 | 186.74 |
| BLTL | 599 | 63 | 63 | 0 | 0 | 173 | 130 | 0 | 0 | 0.546 | 468.08 |
| BLBR | 758 | 149 | 104 | 148 | 121 | 0 | 0 | 0 | 0 | 0.095 | 3.01 |
| THREE | 684 | 151 | 135 | 170 | 132 | 160 | 86 | 0 | 0 | 0.084 | 3.24 |
| FOUR | 769 | 123 | 74 | 148 | 99 | 142 | 80 | 128 | 148 | 0.083 | 2.18 |

TABLE 7
Example design parameters (in nm), normalized MSE (NMSE),
negative log-likelihood, for the Fano-reflection response in FIG. 18C.
Design Parameters

| Structure | p | R1BL | R2BL | R1BR | R2BR | R1TL | R2TL | R1TR | R2TR | NMSE | −log(p) |
|---|---|---|---|---|---|---|---|---|---|---|---|
| One | 672 | 78 | 180 | 0 | 0 | 0 | 0 | 0 | 0 | 0.36 | 276.8 |
| BLTL | 777 | 76 | 64 | 0 | 0 | 168 | 157 | 0 | 0 | 0.31 | 214.26 |
| BLBR | 851 | 143 | 134 | 163 | 132 | 0 | 0 | 0 | 0 | 0.056 | 0.57 |
| THREE | 833 | 172 | 92 | 175 | 175 | 76 | 72 | 0 | 0 | 0.086 | 0.17 |
| FOUR | 7846 | 170 | 150 | 142 | 134 | 153 | 113 | 78 | 78 | 0.099 | 1.24 |

### Example 17—Manifold learning

To form the latent space of the responses, an AE is trained on a total of 6000 reflection responses obtained by 3D FDTD simulations for the random sets of design parameters of the structures in FIG. 16A. Each reflection response is calculated in the 350 nm<λ<800 nm, and it is sampled uniformly with 550 samples in this range. The dimensionality of the reflection responses is reduced from 550 into 2 and 3 using the trained AE with 11 layers (550, 200, 100, 50, 20, d, 20, 50, 100, 200, 550 nodes at each layer, respectively, where d is the dimension of the latent space). The hidden layers have tangent-hyperbolic (tanh(.)) activation functions, and the input and output layers have linear activation functions. The MSE loss is minimized during the training using Adam optimizer in Python. The training is stopped after 500 epochs if the required MSE is not reached. GMMs are used for modeling the sub-manifold of the responses in the latent space for each design complexity. The distance metric is set to correlation, and the maximum distance is 0.3, with a maximum of 5 Gaussian distributions for each model. The GMMs are trained on the training samples in 2D and 3D spaces.

### Example 18—Inverse Design

To find the optimum design parameters, a feed-forward NN is trained from the design to the response space. The network has 8 layers with 9, 20, 50, 100, 100, 200, 400, 500 nodes at each layer. The activation functions of the hidden layers is tanh(.). The design parameters are normalized to have zero mean and unit standard deviation. The weights of the NN are trained using the Adam optimizer in Python to minimize the MSE.

To perform the inverse design with a desired reflection response and a given design complexity (i.e., a given unit-cell structure in FIG. 16A), the inventors use the exhaustive search (with 106 random sets of design parameters) in the design space using the trained feed-forward NN. The optimum solution with minimum mean-squared distance to the desired reflection response for each design complexity is reported as the solution. Note that this is the simplest approach for the inverse design using AI. In a more aggressive approach with less computation requirements, recent techniques like training a pseudo-encoder and combining an inverse AI design (from the response space to the reduced design space) with a considerably smaller exhaustive search (from the design space to the reduced design space), as explained above can be used. All of the AI algorithms are implemented in Python and Keras on a system with Core i7 CPU, one RTX2080 GPU, and 32 GB of RAM.

### Example 19—Electromagnetic Simulations

The 3D FDTD simulations are conducted with the commercial software Lumerical. The simulation domain is limited to one period (p) in the lateral directions (i.e., x and y in FIG. 16A) and perfectly matched layers are used on the top and bottom layers (in the z-direction in FIG. 16A) due to the periodicity of the structures.

### Example 20—Inverse Design of Photonic Nanostructures using Dimensionality Reduction

An example systematic approach for the inverse design of non-unique nanophotonic structures can be based on reducing the dimensionality of the design space and response space (DS and RS, respectively). The inverse design problem can be solved using the reduced DS (RDS) and the reduced RS (RRS), and the computation requirements are reduced by orders of magnitude. The inverse design approach is based on dividing the large overall non-unique (and thus, non-invertible) problem into a combination of a large invertible problem (between the RS and the RDS) and a small non-invertible problem (between the RDS and the original DS). To demonstrate this approach's unique features, the example method as described above was applied to design standard multilayer thin-film structures composed of consecutive layers of silica (SiO₂) and titania (TiO₂). The detailed comparison with the alternative approach based on training a conventional NN without dimensionality reduction shows an improvement by two to three orders of magnitude in the number of floatingpoint operations per second (FLOPS) without imposing a significant error.

FIG. 20A shows the schematic of a FNN that maps the DS to the RS. This is used as the baseline for comparison of the computational performance of different approaches. Considering the DSχ∈ [symbol] ^{d} and the RS [symbol] ∈ [symbol] ^{r}, the FNN is trained to learn the mapping F:χ→ [symbol] with minimal mean-squared error (MSE) between the predicted and simulated responses. Then, for a desired response y∈ [symbol] ᵣ, the trained FNN will be used to search over the DS and find the optimum set of design parameters so that

$${x}^{*} = arg {max}_{x ∈ χ} Loss ( y , {y}^{*} ) ,$$

where y=F(x), y*=F(x*), and Loss(y, y*) is considered as the MSE (i.e., ∥y−y*∥₂²). Although the FNN is significantly faster than an EM simulation software for searching over the DS, the computation will increase as the number of design parameters and the complexity of the structure increase [since a network with more nodes and layers needs to be trained). The first step in the disclosed dimensionality-reduction-based design approach is to reduce the dimensionality of the RS using an autoencoder (AE). FIG. 20B shows the schematic of an AE, which is composed of an encoder that maps the RS to the RRS (Φ: [symbol] → [symbol] ) and a decoder that reconstructs the original response from the RRS (Ψ: [symbol] → [symbol] ). Due to the high redundancy in the response of a photonic nanostructure, the dimensionality of the RS can be reduced extensively without significant error. The optimum dimensionality of the RRS can be found using an ad hoc method by changing the size of the bottleneck layer in FIG. 20B. Once the AE is trained, the inventors can reduce the dimensionality of any given response using the encoder. Next, the inventors consider the pseudoencoder (PE) network (see FIG. 21) to reduce the dimensionality of the DS. The first part of the network (i.e., DS-to-RDS) maps the DS into the RDS. Then the RDS-to-RRS network maps the RDS to the RRS. Finally, using the decoder part of the trained AE, the RRS will be mapped to the original RS. During the training, the MSE will be minimized over the original RS [note that the weights of the decoder part in FIG. 21 are fixed by the trained AE for the RS in FIG. 20B.

As discussed above, the relation between the RDS and the RS in FIG. 21 is one to one and can be inverted, while the mapping between the DS and the RDS is not one to one. To find the inverse relation, the inventors freeze the weights of the RDS-to-RRS network and concatenate it with a similar network from RRS to the RDS and training the RRS-to-RDS to find optimal parameters. Thus, the inverse design approach for a desired response is composed of two steps. First, the inventors use the inverted relation between the RS and the RDS to map the desired response into a single point in the RDS. To simplify this inversion, the inventors use the AE in FIG. 20B to map the desired response to a point in the RRS, which will then be mapped to the corresponding point in the RDS using a trained network between the RRS and RDS. Second, the inventors use the trained DS-to-RDS part of the network in FIG. 21 to search over the DS and find the optimum set(s) of design parameters that maps to the target point in the RDS. By using this two-step process, the inventors considerably reduce the computation as the exhaustive search is performed over the smallest part of the PE in FIG. 21, rather than the entire NN between the DS and the RS as in the conventional NN-based algorithm in FIG. 20A. To show the efficacy of the disclosed method, the inventors perform the inverse design of an eight-layer and a 20-layer thin-film structure, shown in FIG. 22. These structures are composed of consecutive layers of SiO₂ and TiO₂, and the design parameters are the heights of different layers (hᵢ∈[30; 70] nm), while the responses are 200 samples of the transmission spectrum from 300 to 750 THz. This results in dimensionalities of eight and 20 for the DS for the first and second structures, respectively, and 200 for the RS. For comparison purposes, the inventors also train a conventional NN (see FIG. 20A) and use it for inverse design of similar structures. The inverse design in this case is performed through an exhaustive search between the DS and the RS using the FNN. For each structure, the inventors generate 50,000 sets of random design parameters and find the corresponding responses using the transfer matrix approach, implemented in Python. We use 80% of the dataset for training the algorithm and the remaining 20% for testing it. We compare the FLOPS and the normalized MSE (NMSE) for the FNN (FIG. 20A) and the PE (FIG. 21) over the eight-layer and 20-layer datasets.

To investigate the existence of non-uniqueness in the disclosed dataset, the inventors produce sets of design parameters with nearly identical optical spectrums with an accelerated brute-force approach. We use the trained FNN in FIG. 20A to find three sets of design parameters that result in the minimum MSE between the calculated response and the desired response. The FNN used for the eight-layer structure has four hidden layers, each with 100 nodes and tangent hyperbolic (i.e., tanh) as the activation function. After training, the average NMSE over the test set for this network is 1.3 10.5 with 102,200 FLOPS for calculating the response of each test instance. FIGS. 3A and 3B show the result of this investigation for an eight-layer structure. FIG. 23B shows very similar responses for the three selected structures despite major differences between their design parameters provided in FIG. 23A. A similar observation is obtained for the case of 20-layer structures with a slight increase in error. This clearly indicates the presence of sets of non-unique design parameters that need to be addressed during inverse design.

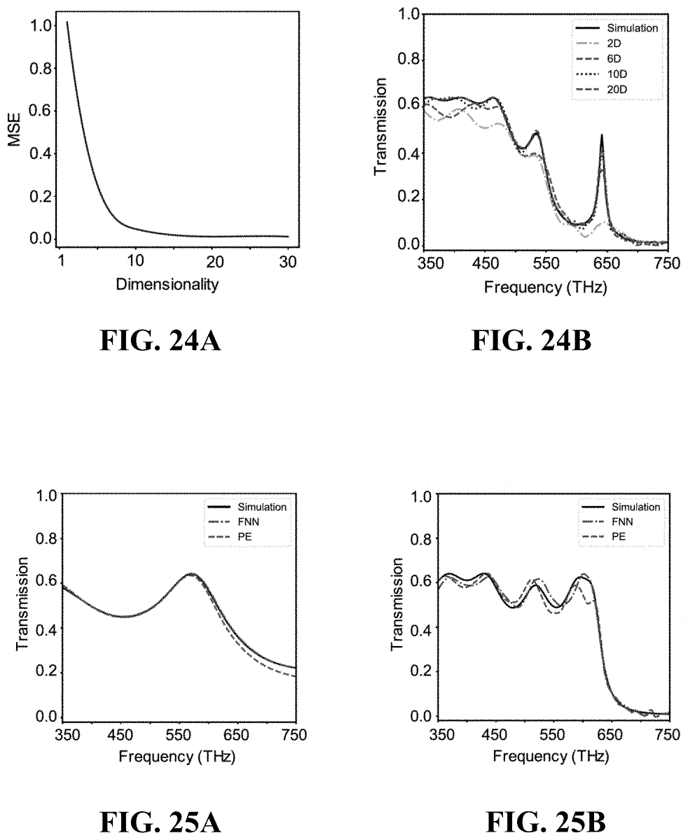

To reduce the dimensionality of the design and RSs for the eight-layer structure, the inventors first train the AE in FIG. 20B using different numbers of nodes for the bottleneck layer to find the optimum dimensionality of the RRS. Our results show that with a nine-layer AE (four layers for the encoder, four layers for the decoder, and one bottleneck layer), the best dimensionality of the RRS is 12 with a NMSE of 2.2 10.6 with 200, 100, 50, 30, 12, 30, 50, 100, and 200 neurons in each layer, respectively. The activation functions of all intermediate layers are tanh(.) with no activation functions in the input and output layers. We will then use a similar ad hoc approach to find the best dimensionality for the RDS by training the PE part of FIG. 21 with a varying size of the bottleneck layer. We find that the optimum dimensionality of the RDS to be three using a PE with a total of eight layers with 8, 5, 5, 3, 100, 50, 30, and 12 nodes in consecutive layers. The average NMSE of the trained PE over the test set is 7.6 10.4 with 14,685 FLOPS (for connecting the DS to the RRS). However, the mapping between the DS and the RDS, which will be needed for the exhaustive search in the inverse design, is performed using the DS-to-RDS network in FIG. 21 with only 173 FLOPS, which is smaller than the number of FLOPS needed for the FNN by a factor of 600. Note that in practice, it is preferred to use a random search (rather than an exhaustive search) for finding the best designs. Nevertheless, the advantage of the dimensionality-reduction approach over the FNN remains the same, as it applies to every step of the search process. The FNN for the 20-layer structure has four hidden layers, each with 300 nodes and tangent hyperbolic (i.e., tanh) as the activation function. This NMSE over the test set for this network is 1.2 10.3 with 673,400 FLOPS for each test instance. Using a similar approach, the dimensionality of the RS for the two-layer structure is reduced to 20 with an average NMSE of 6.2 10.5 using a nine-layer AE with 200, 100, 50, 30, 20, 30, 50, 100, and 200 neurons in each layer, respectively. FIG. 24A shows the variation of the MSE of the AE with the dimensionality of the RRS, and FIG. 24B compares the corresponding responses in the AE with the original response. The corresponding eight-layer PE for this case has layers of 20, 20, 10, 8, 100, 50, 30, and 20 nodes, with the optimum dimensionality of eight for the RDS. The average NMSE of the PE over the test set is 1.1 10.2 with 17,398 FLOPS for the entire PE and 1398 FLOPS for the DS-to-RDS network. This shows a computation advantage over the FNN by a factor of 500. FIGS. 25A and 25B show the performance of the disclosed PE-based approach and the FNN for the inverse design of the eight-layer and 20-layer structures, respectively. In both cases, the desired response was not used in training or testing. Our algorithm uses random search instead of exhaustive search to address the nonuniqueness issue. The results shown in FIGS. 25A and 25B are the designs with the lowest NMSE. The NMSE between the desired (i.e., simulated) and the designed responses in FIG. 25A are 3.4 10.5 and 1.7 10.3 for the FNN and the PE approaches, respectively. The corresponding values of NMSE in FIG. 25B are 2 10.3 and 3.6 10.3 for the FNN and PE, respectively. The reported numbers are average numbers obtained in testing the algorithms for many designs in order to be good representatives of the performance of the two inverse design approaches.

FIGS. 25A and 25B show the advantage of the disclosed PE-based technique in performing the inverse design of a multi-layer structure over the conventional NN-based approaches in achieving similar NMSEs with two to three orders of magnitude reduction in computation. This advantage becomes more important for complex nanostructures with many design parameters where the computation of the FNN algorithm becomes excessive. While the actual computation advantage of the PE-based approach depends on the nature of the problem in both design and RSs, the inventors expect the observed numbers in this disclosure to be good representatives of such an advantage.

It is important to note that the numbers of nodes in the layers of the PE after the bottleneck layer (i.e., the RDS-to-RRS network) do not affect the computation advantage of the PE in inverse design, as the only part used for the final search is the DS-to-RDS network. Nevertheless, it is important to optimize the dimensions of the RDS and RRS to ensure a one-to-one relation between the RDS and the RS to enable the simple inversion from the RS to the RDS. This is currently done by trying different dimensions for the RRS and the RDS. Future research should be performed to develop more rigorous approaches for finding such optimal dimensions.

While the PE-based approach is computationally favorable over the FNN during the inverse design phase, it requires more computation during the training phase since the PE requires training of two separate networks: the AE for the dimensionality reduction of the RS, and the PE for that of the DS. However, training is performed only once for all the inverse design attempts using a given photonic device architecture. Thus, the added training computation is not a major disadvantage of the PE-based approach. Although the inventors considered thin-film structures with 20 layers in this disclosure, the disclosed dimensionality-reduction approach can be used to reduce the computation requirements for structures with any number of layers. The computation advantage of the approach will be even more for more complex structures, especially with careful optimization of the dimension of the latent space based on the acceptable reconstruction error. Note that there is a trade-off between the dimensionality of the latent space (and thus, the computation requirements) and the error in reconstruction of a given response by the AE, as can be seen in FIGS. 24A and 24B.

A unique feature of the demonstrated approach is its generality and applicability for designing and investigating a variety of different nanophotonic structures for different applications, as long as the response features are covered in the training phase. This is in contrast to conventional design approaches where the entire design process has to be repeated once the desired response changes (even slightly).

To summarize, the inventors demonstrated here a reliable and computationally superior AI approach based on dimensionality reduction for analysis and inverse design of photonic nanostructures. The PE-based approach has two to three orders of magnitude reduction in the required computation for the inverse design of a typical photonic nanostructure without imposing much error compared to using a FNN. It also applies to non-unique problems with no major difference. By breaking the large non-unique inverse design problem into a large one-to-one problem and a small non-unique problem, the disclosed PE-based approach can further facilitate the inverse design of photonic nanostructures, especially through employing more rigorous optimization techniques for the last stage (from the RDS to the DS), while such rigorous techniques cannot usually be employed for the original non-unique problem due to the excessive computation requirements.

It is to be understood that the embodiments and claims disclosed herein are not limited in their application to the details of construction and arrangement of the components set forth in the description and illustrated in the drawings. Rather, the description and the drawings provide examples of the embodiments envisioned. The embodiments and claims disclosed herein are further capable of other embodiments and of being practiced and carried out in various ways. Also, it is to be understood that the phraseology and terminology employed herein are for the purposes of description and should not be regarded as limiting the claims.

Accordingly, those skilled in the art will appreciate that the conception upon which the application and claims are based may be readily utilized as a basis for the design of other structures, methods, and systems for carrying out the several purposes of the embodiments and claims presented in this application. It is important, therefore, that the claims be regarded as including such equivalent constructions.

Furthermore, the purpose of the foregoing Abstract is to enable the United States Patent and Trademark Office and the public generally, and especially including the practitioners in the art who are not familiar with patent and legal terms or phraseology, to determine quickly from a cursory inspection the nature and essence of the technical disclosure of the application. The Abstract is neither intended to define the claims of the application, nor is it intended to be limiting to the scope of the claims in any way.

What is claimed:

1. A system (10) for detecting a feasible optical response performance from a structure, the system comprising:
one or more processors;
at least one memory in communication with the one or more processors and configured to store instructions that, when executed by the one or more processors, are configured to cause the system to:
collect input design data (12);
identify, based on the input design data, limitation data (14);
generate, based on the limitation data, simulation data (15) comprising a design space (16) and a response space (17);
train, utilizing the response space, a first multi-layer neural network (18) to generate a reduced response space (20) having reduced dimensionality compared to the response space, the first multi-layer neural network comprising an encoding layer and a decoding layer;
train, utilizing the design space and the response space, a second neural network (22) to generate a reduced design space (24) having reduced dimensionality compared to the design space;
generate, by cascading the second neural network with the decoding layer of the first multi-layer neural network, an optimization convex hull (30); and
invert, using the optimization convex hull, the design space and the response space to generate the feasible optical response performance from the structure.

2. The system of claim 1, wherein the instructions are further configured to cause the system to determine, by using the optimization convex hull, a designation of overlapping or non-overlapping of a desired design space of a desired structure.

3. The system of claim 1, wherein the instructions are further configured to cause the system to validate, by using validation data (40), the optimization convex hull.

4. The system of claim 1, wherein the input design data comprises a plurality of randomly generated patterns of a simulated structure.

5. The system of claim 4, wherein limitation data comprises structural limitation data relating to physical properties of a photonic nanostructure.

6. The system of claim 5, wherein the photonic nanostructure comprises a metasurface. The system of claim 1, wherein the first multi-layer neural network is an autoencoder.

8. The system of claim 7, wherein the autoencoder utilizes mean squared error as a cost function.

9. The system of claim 1, wherein the simulation data comprises a multi-dimensional response space.

10. The system of claim 9, wherein the simulation data comprises at least a six-dimensional response space.

11. The system of claim 1, wherein the response space and the reduced response space have a one-to-one dimensional relationship.

12. The system of claim 1, wherein the reduced design space and the reduced response space have a one-to-one dimensional relationship.

13. A method comprising:
identifying a first plurality of data points comprising a design space and a response space;
computing a first convex hull of all data points in the first plurality of data points;
merging the first convex hull with previous convex hulls to form an optimized convex hull, the previous convex hulls comprising a second plurality of data points comprising previous design spaces and previous response spaces; and
determining, by the optimized convex hull, a feasible optical response performance within an electromagnetic nanostructure.

14. The method of claim 13, further comprising:
inverting, using the optimized convex hull, the design space and the response space to generate the feasible optical response performance from the electromagnetic nanostructure.

15. The method of claim 13, wherein inverting, using the optimized convex hull, the design space and the response space further comprises applying a one-class support vector machine algorithm.

16. The method of claim 13, wherein inverting, using the optimized convex hull, the design space and the response space further comprises designating a desired design space of a desired electromagnetic nanostructure as overlapping or non-overlapping the optimized convex hull.

17. The method of claim 13, further comprising:
merging, using the optimized convex hull and third plurality of data points from a desired electromagnetic nanostructure structure, a re-optimized convex hull when the desired electromagnetic nanostructure comprises a desired design space designated as non-overlapping.

18. A system for detecting a feasible optical response performance from an electromagnetic nanostructure, the system comprising:
one or more processors;
at least one memory in communication with the one or more processors and configured to store instructions that, when executed by the one or more processors, are configured to cause the system to:
collect input electromagnetic nanostructure design data;
identify, based on the input electromagnetic nanostructure design data, structural limitation data comprising material properties, potential nanostructure geometry, periodic/non-periodic, unit-cell structure, and fabrication limitations;
generate, based on the structural limitation data, electromagnetic simulation data comprising a design space, the design space comprising a set of design patterns and a corresponding response space comprising a corresponding set of response patterns;
train, utilizing the corresponding response space, a first multi-layer neural network to generate a reduced response space having reduced dimensionality compared to the corresponding response space, the first multi-layer neural network comprising an encoding layer and a decoding layer;
train, utilizing the design space and the corresponding response space, a second neural network to generate a reduced design space having reduced dimensionality compared to the design space;
generate, by cascading the second neural network with the decoding layer of the first multi-layer neural network, an optimization convex hull; and
invert, using the optimization convex hull, the design space and the corresponding response space to generate the feasible optical response performance from the electromagnetic nanostructure.

19. The system of claim 18, wherein the instructions are further configured to cause the system to determine, by using the optimization convex hull, a designation of overlapping or non-overlapping of a desired design space of a desired structure.

20. The system of claim 18, wherein the electromagnetic simulation data comprises a multi-dimensional response space ranging from about 2-dimensional to about 6-dimensional.
